(19) United States
(12) Patent Application Publication
(10) Pub. No.: US 2013/0109148 A1
(43) Pub. Date: May 2, 2013

(54) METHODS OF FORMING A PATTERN AND METHODS OF MANUFACTURING SEMICONDUCTOR DEVICES USING THE SAME

(71) Applicants: Gyu-Hwan OH, Hwaseong-si (KR); Seung-Pil KO, Hwaseong-si (KR); Byeung-Chul KIM, Suwon-si (KR); Youn-Seon KANG, Yongin-si (KR); Jae-Joo SHIM, Suwon-si (KR); Dong-Hyun IM, Hwaseong-si (KR); Doo-Hwan PARK, Yongin-si (KR); Ki-Seok SUH, Hwaseong-Si (KR)

(72) Inventors: Gyu-Hwan OH, Hwaseong-si (KR); Seung-Pil KO, Hwaseong-si (KR); Byeung-Chul KIM, Suwon-si (KR); Youn-Seon KANG, Yongin-si (KR); Jae-Joo SHIM, Suwon-si (KR); Dong-Hyun IM, Hwaseong-si (KR); Doo-Hwan PARK, Yongin-si (KR); Ki-Seok SUH, Hwaseong-Si (KR)

(73) Assignee: SAMSUNG ELECTRONICS CO., LTD., Suwon-si (KR)

(21) Appl. No.: 13/591,824

(22) Filed: Aug. 22, 2012

(30) Foreign Application Priority Data
Oct. 28, 2011 (KR) 1020110111187

(51) Int. Cl. H01L 21/311; H01L 21/02

(52) U.S. Cl. 438/382; 438/694; 257/E21.249; 257/E21.004

(57) ABSTRACT

In a method of forming a pattern, a first mask layer and a first sacrificial layer may be sequentially formed on an object layer. The first sacrificial layer may be partially etched to form a first sacrificial layer pattern. A second sacrificial layer pattern may be formed on the first mask layer. The second sacrificial layer pattern may enclose a sidewall of the first sacrificial layer pattern. The first sacrificial layer pattern may then be removed. The first mask layer may be partially etched using the second sacrificial layer pattern as an etching mask to form a first mask layer pattern. The object layer may be partially etched using the first mask layer pattern as an etching mask.

### CROSS-REFERENCE TO RELATED APPLICATIONS

This application claims priority under 35 U.S.C. §119 to Korean Patent Application No. 2011-0111187, filed on Oct. 28, 2011 in the Korean Intellectual Property Office (KIPO), the entire disclosure of which is incorporated by reference herein.

### BACKGROUND

1. Field

Example embodiments relate to methods of forming a pattern and/or methods of manufacturing semiconductor devices using the same.

2. Description of the Related Art

As semiconductor devices have become highly integrated, contact holes having a relatively minute line width (for example, less than about 20 nm) need to be formed. A double patterning technology (DPT) process may be utilized to form the contact holes due to a resolution limit of an exposure apparatus.

However, as an aspect ratio of the contact hole becomes larger, an etching amount or an etching time for an object layer, such as silicon oxide, may increase and result in damage or destruction of a mask used for the DPT process.

### SUMMARY

At least one example embodiment provides a method of forming a pattern having a relatively minute line width, for example, less than about 20 nm.

At least one example embodiment provides a method of manufacturing semiconductor devices using the method of forming the pattern.

According to an example embodiment, a method of forming a pattern may include sequentially forming a first mask layer and a first sacrificial layer on an object layer. The first sacrificial layer may be partially etched to form a first sacrificial layer pattern. A second sacrificial layer pattern may be formed on the first mask layer. The second sacrificial layer pattern may enclose a sidewall of the first sacrificial layer pattern. The first sacrificial layer pattern may then be removed. The first mask layer may be partially etched using the second sacrificial layer pattern as an etching mask to form a first mask layer pattern. The object layer may be partially etched using the first mask layer pattern as an etching mask.

In an example embodiment, the first sacrificial layer may be formed using silicon oxide. The second sacrificial layer pattern may be formed using silicon nitride or silicon oxynitride.

In an example embodiment, the first sacrificial layer pattern may be removed using a hydrofluoric acid (HF) solution or a buffer oxide etchant (BOE) solution.

In an example embodiment, the first sacrificial layer pattern may include a plurality of pillars.

In an example embodiment, in the operation of partially etching the first sacrificial layer to form the first sacrificial layer pattern, a second mask layer may be formed on the first sacrificial layer. The second mask layer may be partially etched to form a line pattern extending in a first direction. The line pattern may be partially etched to form a second mask layer pattern. The first sacrificial layer may be partially etched using the second mask layer pattern as an etching mask.

In an example embodiment, the first mask layer and the second mask layer may be formed using polysilicon, and the second mask layer pattern may include a plurality of pillars.

In an example embodiment, in the operation of forming the line pattern, a first hard mask pattern extending in the first direction may be formed on the second mask layer. First spacers may be formed on sidewalls of the first hard mask pattern. The first hard mask pattern may be removed. The second mask layer may be partially etched using the first spacer as an etching mask.

In an example embodiment, the first hard mask pattern may be formed as a silicon based spin-on hard mask (Si—SOH), and the first spacer may be formed using silicon oxide, e.g., middle temperature oxide (MTO), high temperature oxide (HTO) or atomic layer deposition (ALD) oxide.

In an example embodiment, in the operation of partially etching the line pattern to form the second mask layer pattern, a second hard mask pattern may be formed on the first sacrificial layer and the line pattern. The second hard mask pattern may extend in a second direction perpendicular to the first direction. Second spacers may be formed on sidewalls of the second hard mask pattern and on the line pattern. The second hard mask pattern may be removed. The line pattern may be partially etched using the second spacer as an etching mask.

In an example embodiment, the second hard mask pattern may be formed as a silicon based spin-on hard mask (Si—SOH), and the second spacer may be formed using silicon oxide, e.g., middle temperature oxide (MTO), high temperature oxide (HTO) or atomic layer deposition (ALD) oxide.

According to an example embodiment, there is provided a method of manufacturing a semiconductor device. In the method, a first insulating interlayer may be formed on a substrate. The substrate may include an impurity region. A first contact hole may be formed through the first insulating interlayer to expose the impurity region, the contact hole being formed according to a method of forming a pattern, wherein the first insulating interlayer is the object layer.

In an example embodiment, the first sacrificial layer may be formed using silicon oxide, the second sacrificial layer pattern may be formed using silicon nitride or silicon oxynitride, and the first mask layer may be formed using polysilicon.

In an example embodiment, in the operation of forming the diode, a conductive pattern in the first contact hole may be formed. The conductive layer may be in contact with the impurity region. Impurities may be implanted into the conductive pattern.

In an example embodiment, a second insulating interlayer may be formed on the first insulating interlayer and the diode. A second contact hole may be formed through the second insulating interlayer. The second contact hole may expose the diode. A lower electrode in the second contact hole may be formed. A phase change layer pattern may be in contact with the lower electrode. An upper electrode may be formed on the phase change layer pattern.

In an example embodiment, in the operation of forming the second contact hole, a second mask layer and a third sacrificial layer may be sequentially formed on the second insulating interlayer. The third sacrificial layer may be partially etched to form a third sacrificial layer pattern. The third sacrificial layer pattern may include a plurality of pillars. A fourth sacrificial layer pattern may be formed on the second mask layer. The fourth sacrificial layer pattern may enclose a sidewall of the third sacrificial layer pattern. The third sacrificial layer pattern may be removed. The second mask layer may be partially etched using the fourth sacrificial layer pattern as an etching mask to form a second mask layer pattern. The second insulating interlayer may be partially etched using the second mask layer pattern as an etching mask.

According to an example embodiment, a mask layer may be formed on an object layer and a first sacrificial layer pattern having a substantially pillar shape may be formed on the mask layer. A second sacrificial layer enclosing the first sacrificial layer pattern may be formed on the mask layer. The first sacrificial layer pattern may be removed to form a second sacrificial layer pattern. The mask layer may be etched using the second sacrificial layer pattern as an etching mask to form a mask layer pattern serving as a single-layered etching mask. The object layer may be partially etched using the mask layer pattern as an etching mask to form a contact hole. The shape of the first sacrificial layer pattern may be transferred to the mask layer, thereby to obtain the single-layered etching mask. Therefore, a height of the etching mask may be reduced so that damage and/or collapse of the etching mask may be reduced (or alternatively, prevented).

According to an example embodiment, a method of forming a pattern may include sequentially forming an etch stop layer, a first sacrificial layer, and a first mask layer on an object layer. The first mask layer may be etched (for example, partially etched) to form a first mask layer pattern. The first sacrificial layer may be etched (for example, partially etched) using the first mask layer pattern as an etching mask to form a first sacrificial layer pattern. A second mask layer may be formed on the first sacrificial layer pattern and the etch stop layer. The second mask layer may be etched (for example, partially etched) to form a second mask layer pattern exposing the etch stop layer and the first sacrificial layer pattern. The first sacrificial layer pattern may be etched (for example, partially etched) using the second mask layer pattern as an etching mask to form first sacrificial layer pillars and an opening. A third mask layer may be formed in the opening. The third mask layer may be planarized to expose the first sacrificial layer pillars. The first sacrificial layer pillars may be etched (for example, partially etched) to form holes in the third mask layer. The etch stop layer and the object layer may be etched (for example, partially etched) using the third mask layer as an etching mask to form the pattern.

According to an example embodiment, a method of forming a semiconductor device may include forming a first insulating interlayer on a substrate, the substrate including an impurity region. A contact hole may be formed through the first insulating interlayer to expose the impurity region. A diode may be formed in the first contact hole on the substrate, and the contact hole may be formed according to a method of forming the pattern, wherein the first insulating interlayer is the object layer.

According to an example embodiment, a method of forming a pattern may include sequentially forming a first layer and a second layer on a substrate. The second layer may be etched (for example, partially etched) to form a first pattern layer. A second pattern layer may be formed on the first pattern layer. The first pattern layer, the second pattern layer and the second layer may be etched (for example, partially etched) to form pillars. A third layer may be formed on the first layer, the third layer enclosing the pillars. The pillars, the first layer and the substrate may be etched (for example, partially etched) using the third layer as an etching mask.

According to an example embodiment, a method of forming a semiconductor device may include forming a first insulating interlayer on a substrate, the substrate including an impurity region. A first contact hole may be formed through the first insulating interlayer to expose the impurity region. A diode may be formed in the first contact hole on the substrate. Forming the first contact hole may include sequentially forming a first layer and a second layer on the first insulating interlayer. The second layer may be etched (for example partially etched) to form a first pattern layer. A second pattern layer may be formed on the first pattern layer. The first pattern layer, the second pattern layer and the second layer may be etched (for example, partially etched) to form pillars. A third layer may be formed on the first layer, the third layer enclosing the pillars. The pillars, the first layer and the first insulating interlayer may be etched (for example, partially etched) using the third layer as an etching mask.

### BRIEF DESCRIPTION OF THE DRAWINGS

Example embodiments will be more clearly understood from the following detailed description taken in conjunction with the accompanying drawings. FIGS. 1 to 46 represent non-limiting, example embodiments as described herein.

FIGS. 1 to 13 are perspective views illustrating a method of forming a pattern in accordance with example embodiments;

FIGS. 14 to 22 are cross-sectional views illustrating a method of forming a pattern in accordance with some example embodiments;

FIGS. 23 to 30 are cross-sectional views illustrating a method of manufacturing a semiconductor device in accordance with example embodiments;

FIGS. 31 to 33 are cross-sectional views illustrating a method of manufacturing a semiconductor device in accordance with some example embodiments;

FIGS. 34 to 42 are cross-sectional views illustrating a method of manufacturing a semiconductor device in accordance with some example embodiments; and

FIGS. 43 to 46 are cross-sectional views illustrating a method of manufacturing a semiconductor device in accordance with some example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DESCRIPTION OF EXAMPLE EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of present inventive concepts.

Spatially relative terms, such as “beneath,” “below,” “lower,” “above,” “upper”and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to limit present inventive concepts. As used herein, the singular forms “a,” “an” and “the” are intended to include the plural forms as well, unless the context clearly indicates otherwise. It will be further understood that the terms “comprises,” “comprising,” “includes” and/or “including when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of present inventive concepts.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

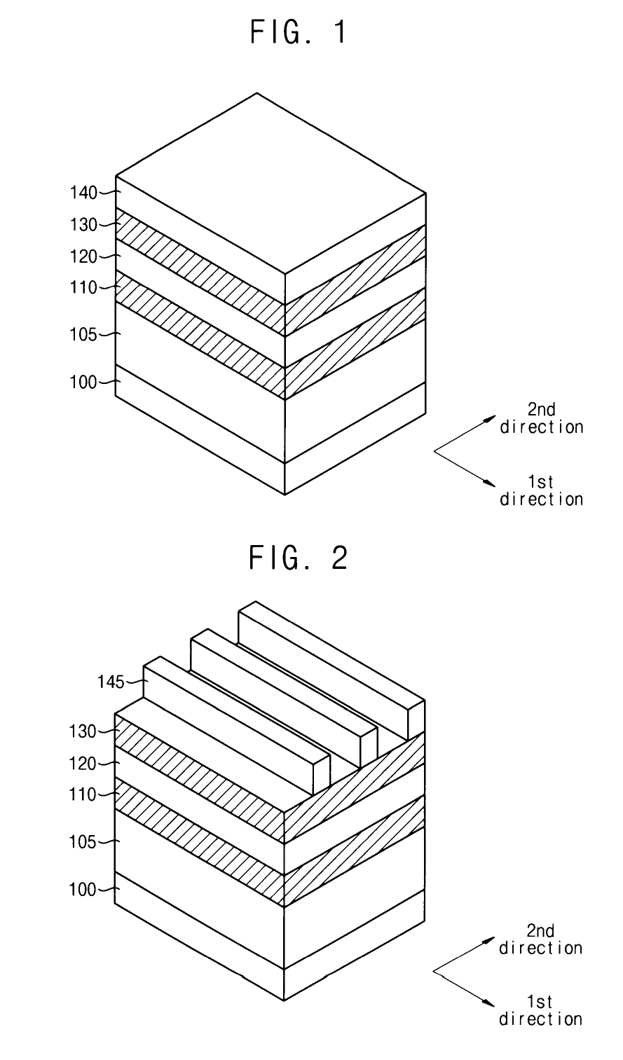

FIGS. 1 to 13 are perspective views illustrating a method of forming a pattern in accordance with example embodiments.

Referring to FIG. 1, an object layer 105, a first mask layer 110, a first sacrificial layer 120, a second mask layer 130 and a first hard mask layer 140 may be sequentially formed on a substrate 100.

The substrate 100 may include a semiconductor substrate such as a silicon substrate, a germanium substrate, a silicon-germanium substrate, a silicon-on-insulator (SOI) substrate, a germanium-on-insulator (GOI) substrate, etc. A conductive structure (not illustrated) including, e.g., a metal, a metal nitride or a metal silicide and/or an insulation structure (not illustrated) may be further formed on the substrate 100.

The object layer 105 may be formed using a silicon oxide such as phosphor silicate glass (PSG), boro-phosphor silicate glass (BPSG), undoped silicate glass (USG), tetra ethyl ortho silicate (TEOS), plasma enhanced-TEOS (TEOS), high density plasma-chemical vapor deposition (HDP-CVD) oxide, etc., or silicon nitride. The object layer 105 may be formed using a chemical vapor deposition (CVD) process, a plasma enhanced chemical vapor deposition (PECVD) process, a spin coating process, a high density plasma-chemical vapor deposition (HDP-CVD) process, a low pressure chemical vapor deposition (LPCVD) process, etc.

The first mask layer 110 may be formed using a material that may have an etching selectivity with respect to an oxide and/or a nitride. For example, the first mask layer 110 may be formed using polysilicon. The first mask layer 110 may be formed by a CVD process, a sputtering process, a physical vapor deposition (PVD) process, an atomic layer deposition (ALD) process, etc.

The first sacrificial layer 120 may be formed using silicon oxide such as PSG, BPSG, USG, TEOS, PE-TEOS, HDP-CVD oxide, etc., by, e.g., a CVD process.

The second mask layer 130 may be formed using a material that may have an etching selectivity with respect to an oxide and/or a nitride. For example, the second mask layer 130 may be formed using polysilicon. The second mask layer 130 may be formed by a CVD process, a sputtering process, a PVD process, an ALD process, etc. In example embodiments, both the first and second mask layers 110 and 130 may be formed using polysilicon.

The first hard mask layer 140 may be formed as a silicon based spin-on hard mask (Si—SOH), e.g., a spin-on glass (SOG) layer.

An anti-reflective layer (not illustrated) may be further formed on the first hard mask layer 140. The anti-reflective layer may be formed using, e.g., silicon oxynitride by a spin coating process, a CVD process, etc.

Referring to FIG. 2, a photoresist pattern (not illustrated) may be formed on the first hard mask layer 140. The first hard mask layer 140 may be partially etched using the photoresist pattern as an etching mask to form a first hard mask pattern 145. For example, the first hard mask layer 140 may be etched by a dry etching process using a gas mixture of CHF₃ and CF₄ as an etching gas.

In example embodiments, the first hard mask pattern 145 may have a substantially linear shape extending in a first direction, and a plurality of the first hard mask patterns 145 may be formed along a second direction substantially perpendicular to the first direction. A top surface of the second mask layer 130 may be partially exposed between the adjacent first hard mask patterns 145.

The photoresist pattern may be removed by an ashing process and/or a strip process.

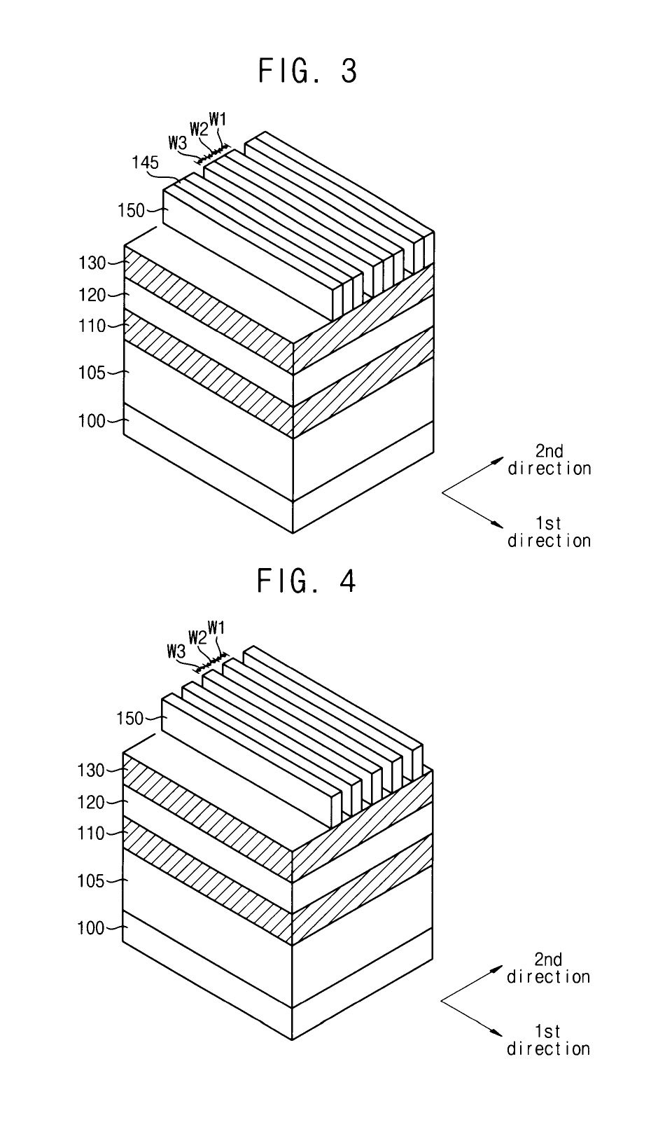

Referring to FIG. 3, first spacers 150 may be formed on both sidewalls of the first hard mask pattern 145. In example embodiments, a first spacer layer covering the first hard mask patterns 145 may be formed on the second mask layer 130. The first spacer layer may be partially removed by an etch-back process to form the first spacer 150. The first spacer 150 may extend in the first direction on the sidewall of the first hard mask pattern 145. The first spacer layer may be formed using, e.g., middle temperature oxide (MTO), high temperature oxide (HTO) or ALD oxide.

In example embodiments, a line width of the first hard mask pattern 145 (W1), a line width of the first spacer 150 (W2) and a distance (W3) between the adjacent first spacers 150 may be substantially equal, each of which may be less than about 20 nm.

Referring to FIG. 4, the first hard mask pattern 145 may be removed by, e.g., an ashing process. Thus, the top surface of the second mask layer 130 may be exposed between the adjacent first spacers 150.

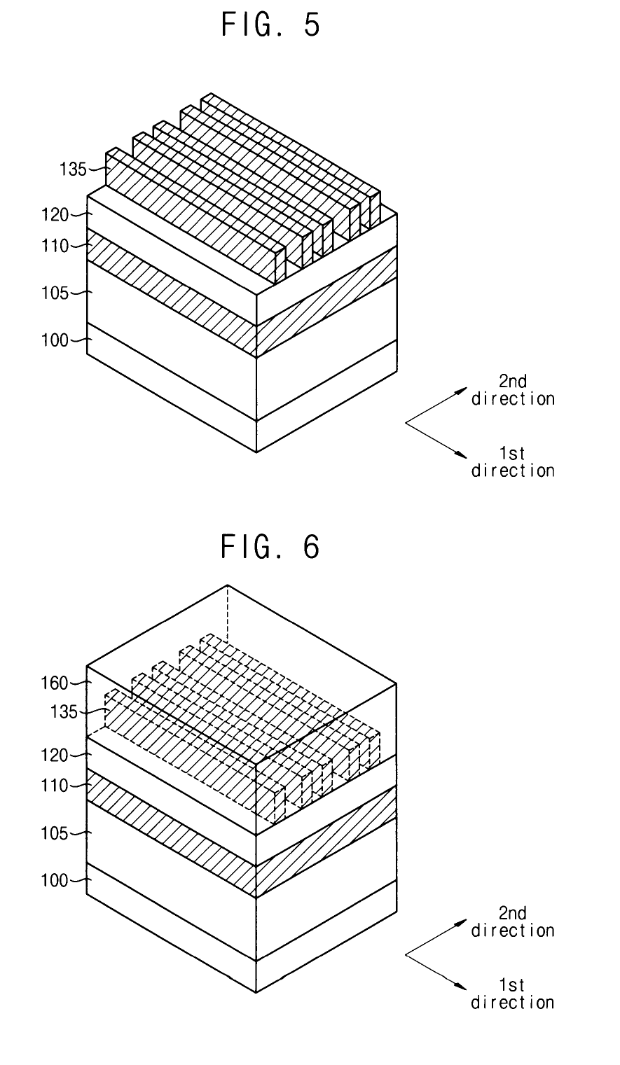

Referring to FIG. 5, the second mask layer 130 may be partially etched using the first spacer 150 as an etching mask to form a line pattern 135. In example embodiments, the line pattern 135 may extend in the first direction, and a plurality of the line patterns 135 may be formed along the second direction. A top surface of the first sacrificial layer 120 may be partially exposed between the adjacent line patterns 135. In example embodiments, the etching process may include a dry etching process or a wet etching process utilizing an etching gas or an etching solution that may have an etching selectivity for the second mask layer 130 (including, e.g., polysilicon) relative to the first spacer 150 including, e.g., silicon oxide.

As described above, the line pattern 135 may be formed by a self-aligned reverse patterning (SARP) process. In example embodiments, the first spacers 150 may be formed on the sidewalls of the first hard mask pattern 145, and the first hard mask pattern 145 may be removed. The second mask layer 130 may be etched using the first spacer 150 as the etching mask to form the line pattern 135.

Referring to FIG. 6, a second hard mask layer 160 covering the line patterns 135 may be formed on the first sacrificial layer 120. The second hard mask layer 160 may be formed of a silicon based spin-on hard mask (Si—SOH), e.g., a spin-on glass (SOG) layer. The second hard mask layer 160 may be formed by a spin-coating process, a CVD process, etc. The second hard mask layer 160 may be formed of the same material as the first hard mask layer 140.

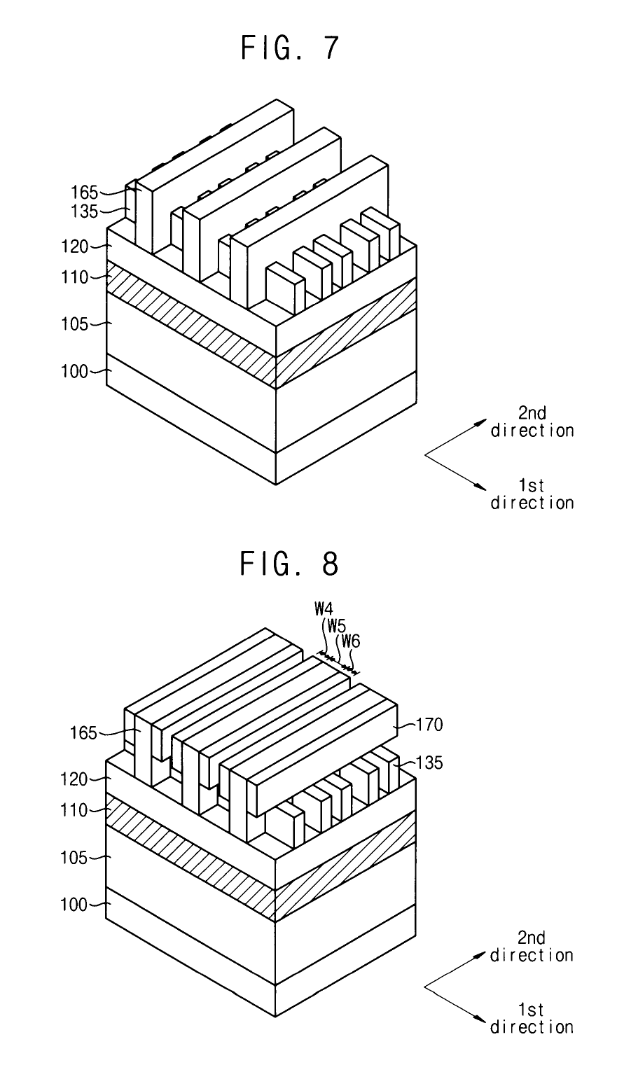

Referring to FIG. 7, the second hard mask layer 160 may be partially etched to form a second hard mask pattern 165 extending in the second direction on the first sacrificial layer 120 and the line pattern 135. A plurality of the second hard mask patterns 165 may be formed along the first direction. For example, the first hard mask layer 160 may be etched by a dry etching process using a gas mixture of CHF₃ and CF₄ as an etching gas.

In example embodiments, a photoresist pattern (not illustrated) extending in the second direction may be formed on the second hard mask layer 160. In one example embodiment, an anti-reflective layer (not illustrated) may be further formed on the second hard mask layer 160 before forming the photoresist pattern. The second hard mask layer 160 may be partially etched using the photoresist pattern as an etching mask to form the second hard mask pattern 165. The photoresist pattern may be removed by an ashing process and/or a strip process.

Referring to FIG. 8, second spacers 170 may be formed on both sidewalls of the second mask pattern 165 and on the line patterns 135. In example embodiments, the second spacer 170 may be formed by a process substantially the same as or similar to that for forming the first spacer 150. For example, a second spacer layer covering the second hard mask pattern 165 may be formed on the first sacrificial layer 120 and the line pattern 135. The second spacer layer may be partially removed by, e.g., an etch-back process to form the second spacer 170 extending in the second direction. The second spacer layer may be formed using silicon oxide, e.g., MTO, HTO, ALD oxide, etc.

In example embodiments, a line width of the second hard mask pattern 165 (W4), a line width of the second spacer 170 (W5) and a distance (W6) between the adjacent second spacers 170 may be substantially equal, each of which may be less than about 20 nm.

The second hard mask pattern 165 between the second spacers 170 may be removed by, e.g., an ashing process. Thus, the second spacers 170 may extend in the second direction on the line patterns 135 extending in the first direction. The second spacers 170 may be arranged to be spaced apart from each other by a desired (or alternatively, predetermined) distance along the first direction.

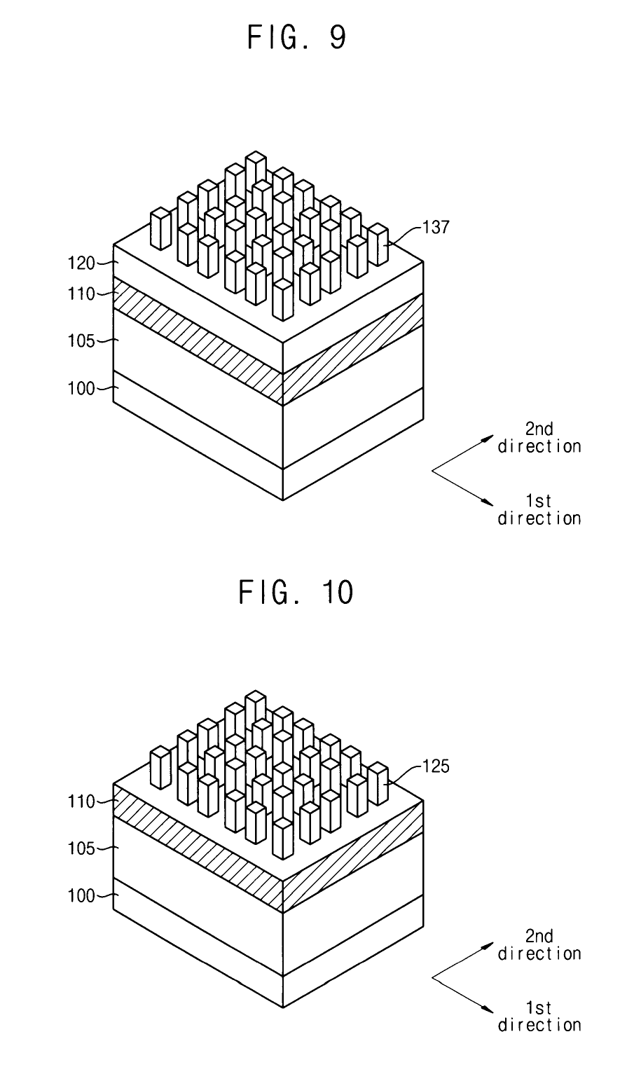

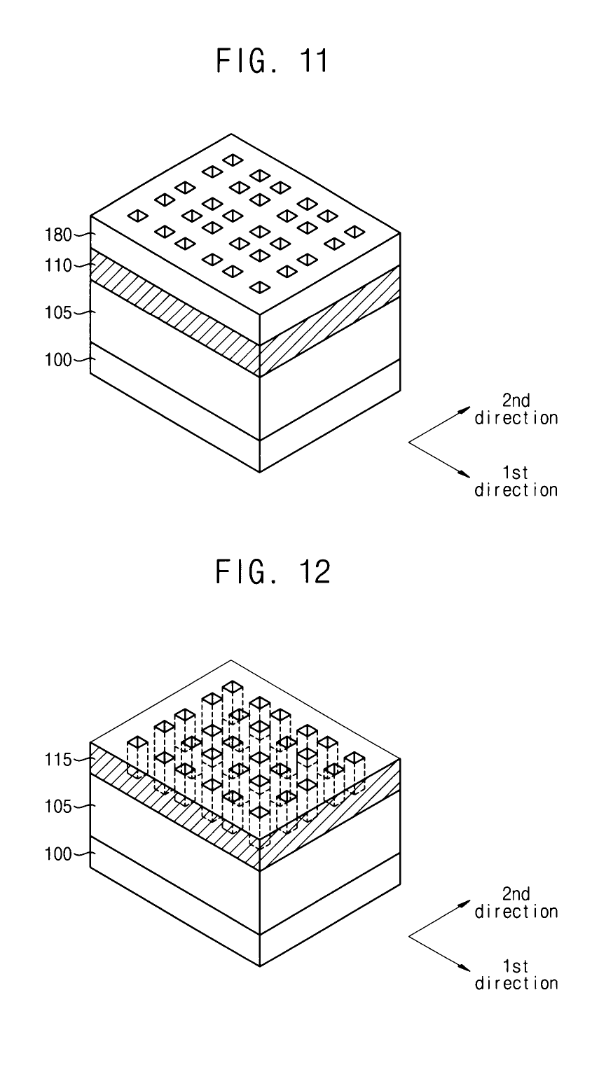

Referring to FIG. 9, the line pattern 135 may be etched using the second spacer 170 as an etching mask to form a second mask layer pattern 137. The second spacer 170 may be removed by, e.g., an ashing process and/or a strip process. In example embodiments, the second mask layer pattern 137 may have a substantially pillar shape. A plurality of the second mask layer patterns 137 may be arranged along the second direction to define a pillar row, and a plurality of the pillar rows may be arranged along the first direction.

Referring to FIG. 10, the first sacrificial layer 120 may be partially etched using the second mask layer pattern 137 as an etching mask to form a first sacrificial layer pattern 125. The etching process may include a wet etching process utilizing an etching solution that may have an etching selectivity for silicon oxide. The etching solution may include a hydrofluoric acid (HF) solution, an LAL solution, a buffer oxide etchant (BOE) solution, etc. Alternatively, the etching process may include a dry etching process. The second mask layer pattern 137 may be removed by, e.g., a strip process.

In example embodiments, the first sacrificial layer 125 may have a shape substantially the same as or similar to that of the second mask layer pattern 137. For example, the first sacrificial layer pattern 125 may have a substantially pillar shape. A plurality of the first sacrificial layer patterns 125 may be arranged on the first mask layer 110 at regular intervals along the first and second directions.

Referring to FIG. 11, a second sacrificial layer covering the first sacrificial layer pattern 125 may be formed on the first mask layer 110. The second sacrificial layer may be formed using silicon nitride or silicon oxynitride. An upper portion of the second sacrificial layer may be planarized by a chemical mechanical polishing (CMP) process or an etch-back process until a top surface of the first sacrificial layer pattern 125 is exposed to form a second sacrificial layer pattern 180.

The first sacrificial layer pattern 125 included in the second sacrificial layer pattern 180 may be removed by a wet etching process utilizing an etching solution that may have an etching selectivity for silicon oxide. The etching solution may include, e.g., an HF solution, a BOE solution or an LAL solution. A top surface of the first mask layer 110 may be partially exposed by a space from which the first sacrificial layer pattern 125 is removed.

Referring to FIG. 12, a first mask layer 110 may be partially etched using the second sacrificial layer pattern 180 as an etching mask to form a first mask layer pattern 115. The second sacrificial layer pattern 180 may be removed by, e.g., a CMP process or an etch-back process. In example embodiments, the first mask layer 110 may be etched by a wet etching process or a dry etching process utilizing an etching solution or an etching gas that may have an etching selectivity for polysilicon relative to silicon nitride or silicon oxynitride.

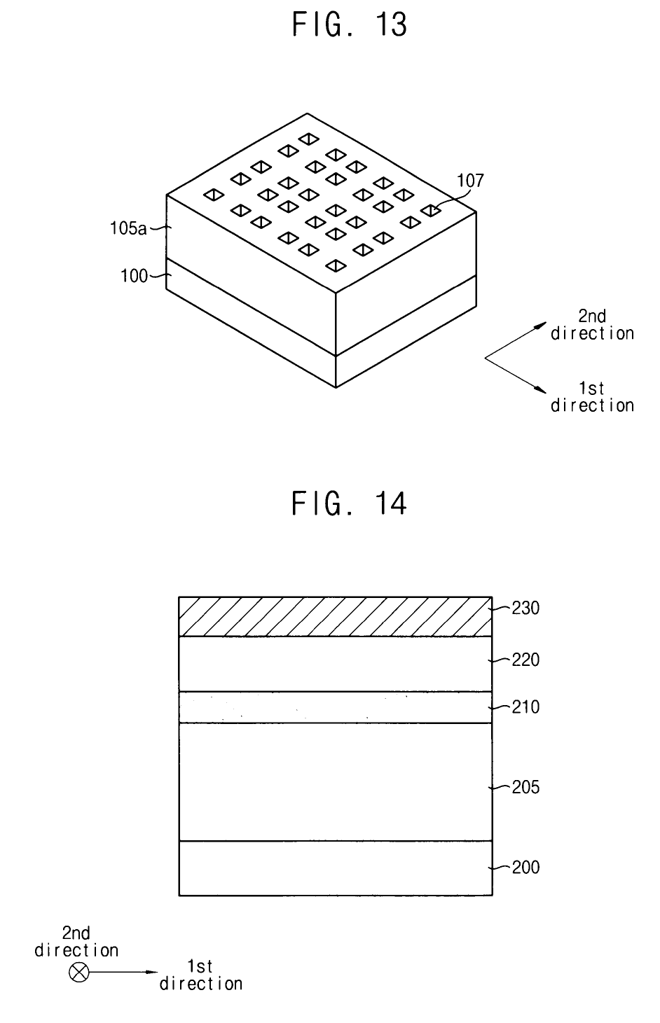

Referring to FIG. 13, the object layer 105 may be etched using the first mask layer pattern 115 as an etching mask to form an object layer pattern 105a including a contact hole 107 therethrough. The etching process may include a dry etching process. In example embodiments, a plurality of the contact holes 107 may be formed and a top surface of the substrate 100 may be exposed by the contact hole 107. The first mask layer pattern 115 may be removed by a CMP process or an etch-back process. In example embodiments, the contact hole 107 may have a width less than about 20 nm.

According to example embodiments, a single-layered mask pattern, i.e., the first mask layer pattern 115 may replace a double-layered mask pattern for a DPT process including line patterns that cross each other. As described above, pillars corresponding to contact holes may be formed on the first mask layer 110 and a shape of the pillars may be transferred to the first mask layer 110 to form the single-layered mask pattern. Thus, a height of the mask pattern may be reduced so that damage or collapse of the mask pattern may be reduced (or alternatively, prevented) during an etching process.

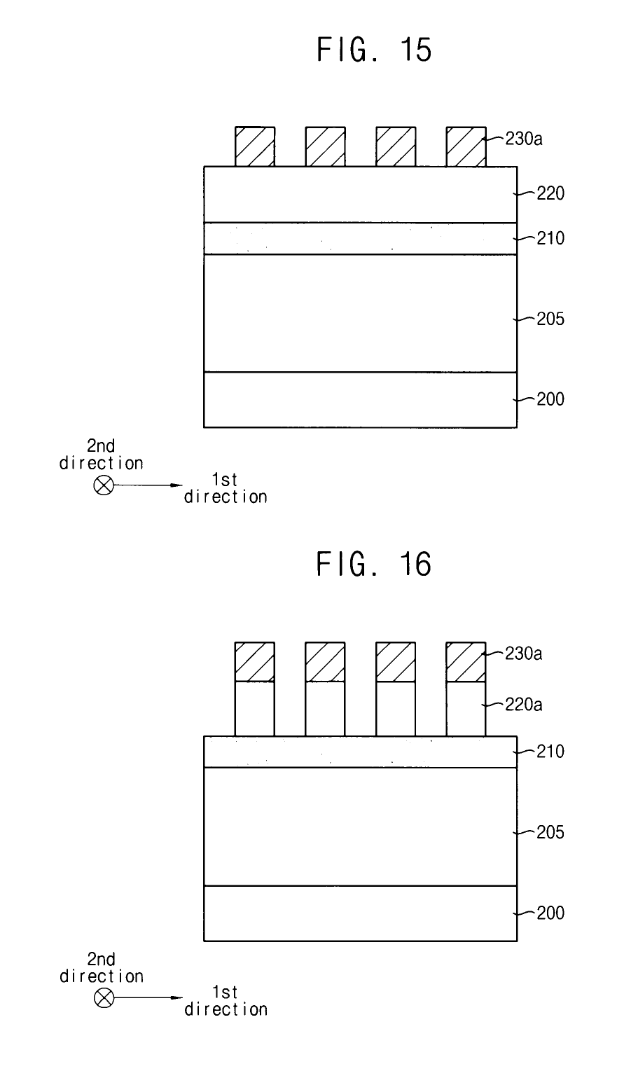

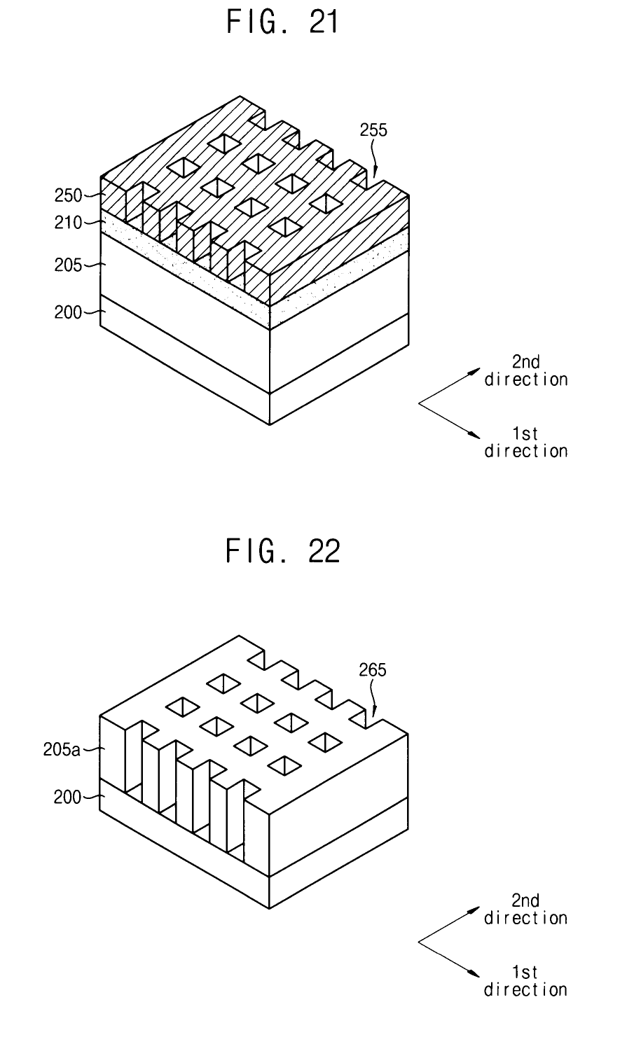

FIGS. 14 to 22 are cross-sectional, top-plan and perspective views illustrating a method of forming a pattern in accordance with some example embodiments. Specifically, FIGS. 14 to 17, 18A, 19A and 20A are cross-sectional views taken along a first direction illustrating the method of forming the pattern. FIGS. 18B, 19B and 20B are cross-sectional views taken along a second direction substantially perpendicular to the first direction illustrating the method of forming the pattern. FIGS. 18C, 19C and 20C are top plan views illustrating the method of forming the pattern. FIGS. 21 and 22 are perspective views illustrating the method of forming the pattern.

Referring to FIG. 14, an object layer 205, an etch-stop layer 210, a sacrificial layer 220 and a first mask layer 230 may be sequentially formed on a substrate 200.

The substrate 200 may include a semiconductor substrate such as a silicon substrate, a germanium substrate, a silicon-germanium substrate, a silicon-on-insulator (SOI) substrate, a germanium-on-insulator (GOI) substrate, etc. A conductive structure (not illustrated) including an impurity region, an electrode, a conductive layer and/or an insulation structure (not illustrated) may be further formed on the substrate 200.

The object layer 205 may be formed using a silicon oxide such as PSG, BPSG, USG, TEOS, TEOS, HDP-CVD oxide, etc., or silicon nitride. The object layer 205 may be formed by a CVD process, a PECVD process, a spin coating process, a HDP-CVD process, a LPCVD process, etc.

The etch-stop layer 210 may be formed using silicon nitride by, e.g., a CVD process.

The sacrificial layer 220 may be formed using silicon oxide such as PSG, BPSG, USG, TEOS, PE-TEOS, HDP-CVD oxide, etc., by, e.g., a CVD process.

The first mask layer 230 may be formed using a material that may have an etching selectivity relative to an oxide and/or a nitride. In example embodiments, the first mask layer 230 may be formed using polysilicon by a CVD process, a sputtering process, a PVD process, an ALD process, etc.

Referring to FIG. 15, the first mask layer 230 may be partially etched to form a first mask layer pattern 230a extending in the second direction. In example embodiments, a plurality of the first mask layer patterns 230a may be arranged on the sacrificial layer 220 to be spaced apart from each other by a desired (or alternatively, predetermined) distance.

In example embodiments, the first mask layer patterns 230a may be formed by processes substantially the same as or similar to those for forming the line pattern 135, as illustrated with reference to FIGS. 1 to 5. For example, the first mask layer patterns 230a may be formed by an SARP process.

Referring to FIG. 16, the sacrificial layer 220 may be partially etched using the first mask layer pattern 230a as an etching mask to form a sacrificial layer pattern 220a. A top surface of the etch-stop layer 210 may be exposed between the adjacent sacrificial layer patterns 220a.

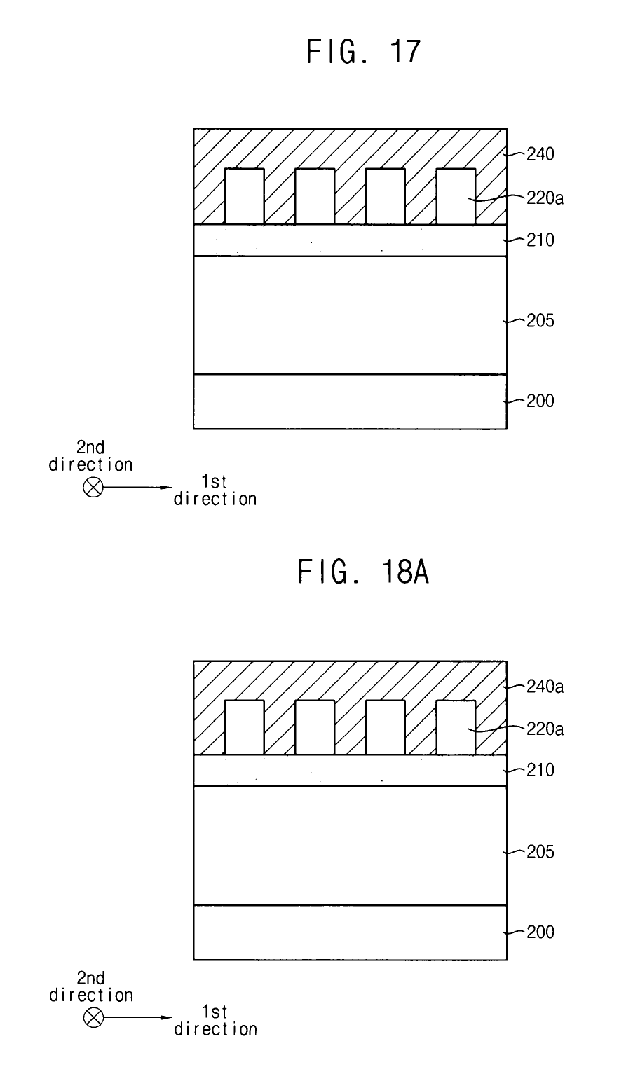

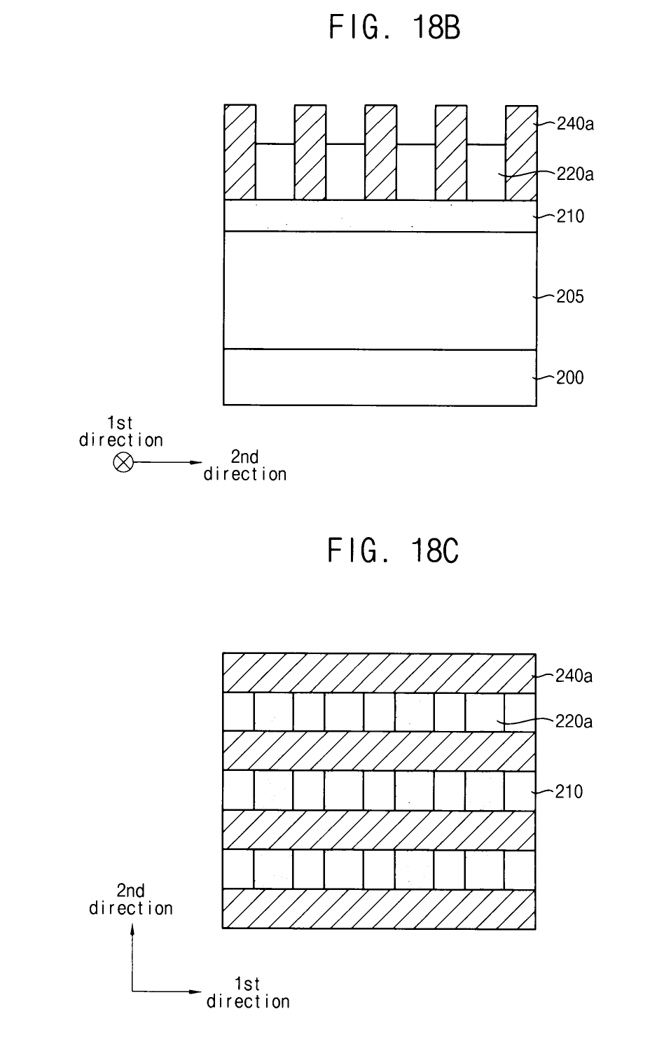

Referring to FIG. 17, a second mask layer 240 covering the sacrificial layer pattern 220a and the first mask layer pattern 230a may be formed on the etch-stop layer 210. In example embodiments, the second mask layer 240 may be formed using polysilicon and may be merged with the first mask layer pattern 230a.

Referring to FIGS. 18A, 18B and 18C, the second mask layer 240 may be partially etched to form a second mask layer pattern 240a extending in the first direction. In example embodiments, a plurality of the second mask layer patterns 240a may be arranged to be spaced apart from each other along the second direction by a desired (or alternatively, predetermined) distance.

In example embodiments, the second mask layer pattern 240a may be formed by processes substantially the same as or similar to those for forming the line pattern 135, as illustrated with reference to FIGS. 1 to 5. For example, the second mask layer pattern 240a may be formed by an SARP process.

As illustrated in FIG. 18C, a portion of the second mask layer 240 exposed between the adjacent second mask layer patterns 240a may be also removed so that the top surface of the etch-stop layer 210 may be partially exposed.

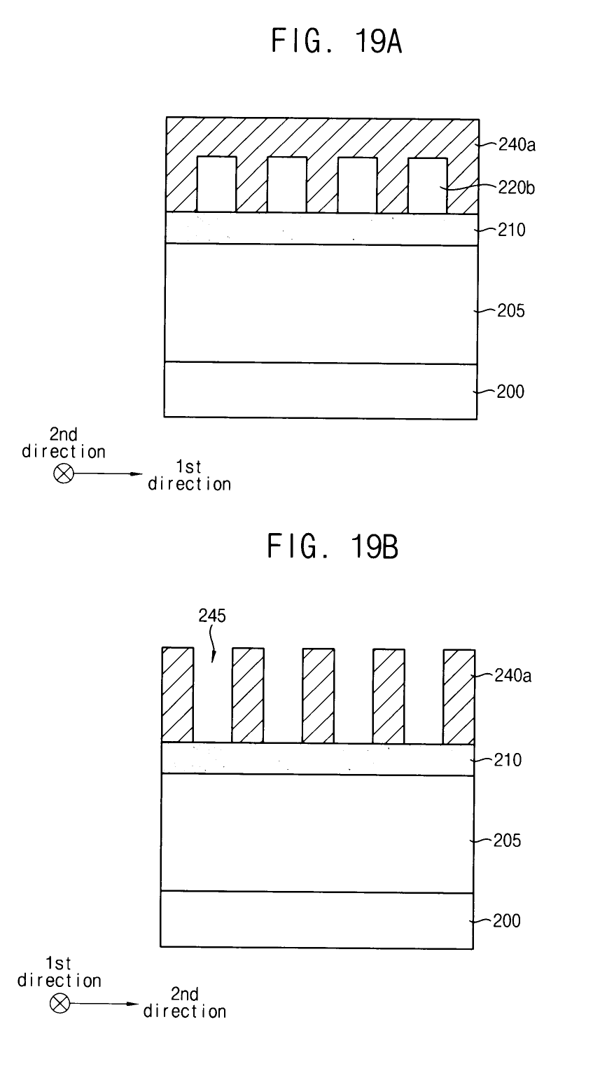

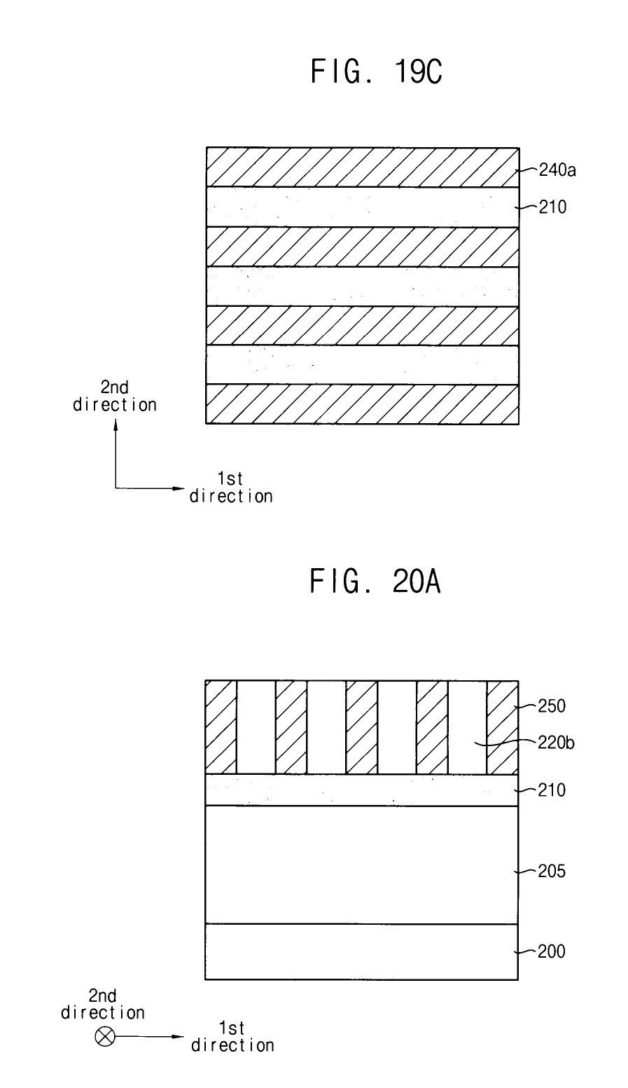

Referring to FIGS. 19A, 19B and 19C, a portion of the sacrificial layer pattern 220a exposed between the adjacent second mask layer patterns 240a may be etched. Accordingly, an opening 245 exposing the top surface of the etch-stop layer 210 may be formed between the adjacent second mask layer patterns 240a as illustrated in FIG. 19B. As illustrated in FIG. 19A, a plurality of sacrificial layer pillars 220b spaced apart from each other by a desired (or alternatively, predetermined) distance along the first direction may be formed under the second mask layer pattern 240a.

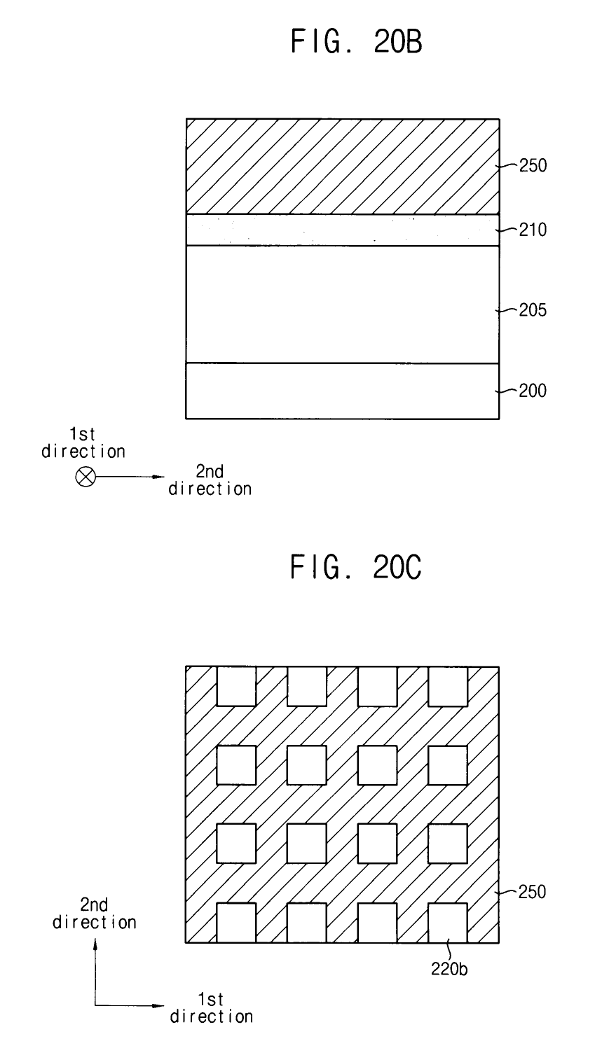

Referring to FIGS. 20A, 20B and 20C, a third mask layer sufficiently filling the opening 245 may be formed on the etch-stop layer 210. In example embodiments, the third mask layer may be formed using polysilicon. The third mask layer may be merged with the second mask layer pattern 240a. An upper portion of the third mask layer may be planarized until a top surface of the sacrificial layer pillar 220b is exposed to form a third mask layer pattern 250. The planarization process may include a CMP process and/or an etch-back process.

Referring to FIG. 21, the sacrificial layer pillar 220b included in the third mask layer pattern 250 may be removed to form a hole 255. A plurality of the holes 255 may be formed to expose the etch-stop layer 210. In example embodiments, the sacrificial layer pillar 220b may be removed by a wet etching process utilizing an etching solution that may include an HF solution, a LAL solution, a BOE solution, etc.

Referring to FIG. 22, the etch-stop layer 210 and the object layer 205 may be sequentially etched using the third mask pattern 250 as an etching mask to form a contact hole 265 and an object layer pattern 205a. A plurality of the contact holes 265 may be formed to expose a top surface of the substrate 200. In example embodiments, the etching process may include a dry etching process. The third mask layer pattern 250 and the etch-stop layer 210 may be removed by, e.g., a CMP process or an etch-back process.

According to example embodiments, a single-layered mask pattern, i.e., the third mask layer pattern 250, may be formed utilizing the sacrificial layer pillars 220b which may correspond to the contact hole 265. Thus, a height of the mask pattern for forming the contact hole that may have a relatively minute line width (for example, less than about 20 nm). Additionally, an aspect ratio of the mask pattern may be decreased so that damage or collapse of the mask pattern may be reduced (or alternatively, prevented) during the etching process.

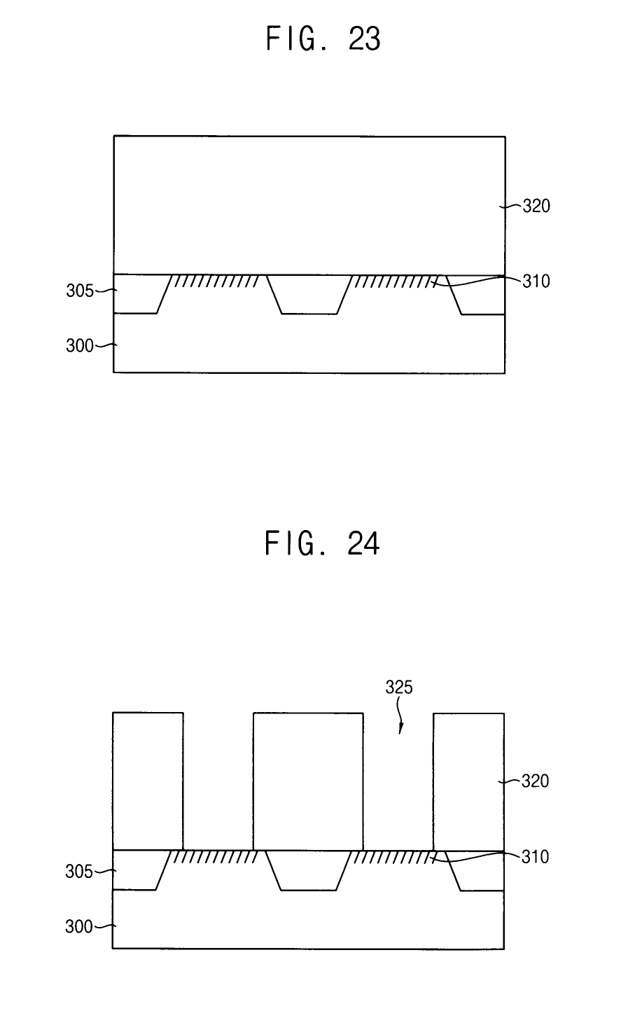

FIGS. 23 to 30 are cross-sectional views illustrating a method of manufacturing a semiconductor device in accordance with example embodiments. Specifically, FIGS. 23 to 30 illustrate a method of manufacturing a phase change memory device according to example embodiments.

Referring to FIG. 23, an isolation layer 305 may be formed on a substrate 300 to define an active region and an isolation region of the substrate 300. An ion-implantation process may be performed to form an impurity region 310 at an upper portion of the substrate 300 in the active region. The isolation layer 305 may be formed by a shallow trench isolation (STI) process. The impurity region 310 may include, e.g., N-type impurities.

A first insulating interlayer 320 may be formed on the substrate 300 and the isolation layer 305. The first insulating interlayer 320 may be formed using, e.g., silicon oxide, silicon nitride or silicon oxynitride by a CVD process, a PECVD process, a spin coating process, an HDP-CVD process, etc.

Referring to FIG. 24, a first contact hole 325 exposing the impurity region 310 may be formed. In example embodiments, the first contact hole 325 may be formed by processes substantially the same as or similar to those illustrated with reference to FIGS. 1 to 13 or FIGS. 14 to 22 using the first insulating interlayer 320 as an object layer.

For example, a single-layered mask pattern may be formed on the first insulating interlayer 320 and the first insulating interlayer 320 may be partially etched using the mask pattern as an etching mask to form the first contact hole 325. The mask pattern may be removed by an ashing process and/or a strip process.

Referring to FIG. 25, a conductive pattern 330 filling the first contact hole 325 may be formed. In example embodiments, a selective epitaxial growth (SEG) process may be performed using the impurity region 310 as a seed to form a conductive layer sufficiently filling the first contact hole. An upper portion of the conductive layer may be planarized until a top surface of the first insulating interlayer 320 is exposed to form the conductive pattern 330. Alternatively, a polysilicon layer sufficiently filling the first contact hole 325 may be formed on the impurity region 310 and the first insulating interlayer 320. The polysilicon layer may be partially planarized to form the conductive pattern 330.

Referring to FIG. 26, impurities may be implanted into the conductive pattern 330 to form a first conductive pattern 332 and a second conductive pattern 334 in the first contact hole 325.

In example embodiments, N-type impurities may be implanted into a lower portion of the conductive pattern 330 to form the first conductive pattern 332, and then P-type impurities may be implanted into an upper portion of the conductive pattern 330 to form the second conductive pattern 334. Thus, a diode 336 in contact with the impurity region 310 may be formed in the first contact hole 325.

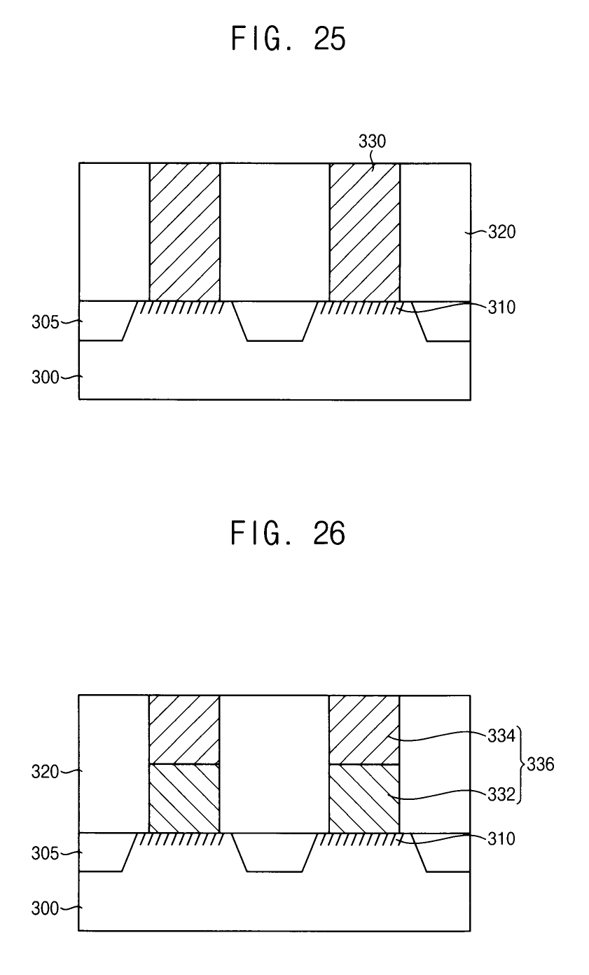

Referring to FIG. 27, a silicidation process may be performed on the diode 336 to transform an upper portion of the diode 336 into a silicide pattern 338.

In one example embodiment, the diode 336 may be formed to partially fill the first contact hole 325 and a metal pattern (not illustrated) may be formed to fill a remaining portion of the first contact hole 325. The metal pattern may be formed using a metal or a metal nitride such as titanium, titanium nitride, tungsten, tungsten nitride, aluminum, aluminum nitride, etc.

Referring to FIG. 28, a second insulating interlayer 340 may be formed on the first insulating interlayer 320 and the silicide pattern 338. The second insulating interlayer 340 may be partially etched to form a second contact hole 345 partially exposing the silicide pattern 338.

In example embodiments, the second contact hole 345 may have a width smaller than that of the first contact hole 325. The second contact hole 345 may be formed by processes substantially the same as or similar to those illustrated with reference to FIGS. 1 to 13 or FIGS. 14 to 22 using the second insulating interlayer 340 as an object layer.

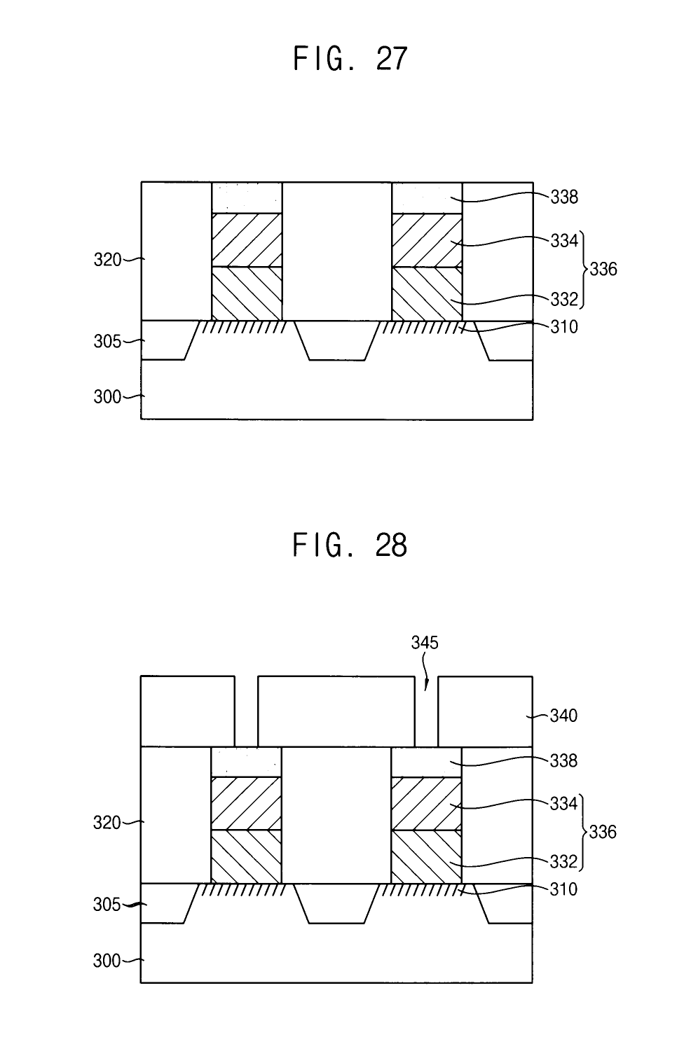

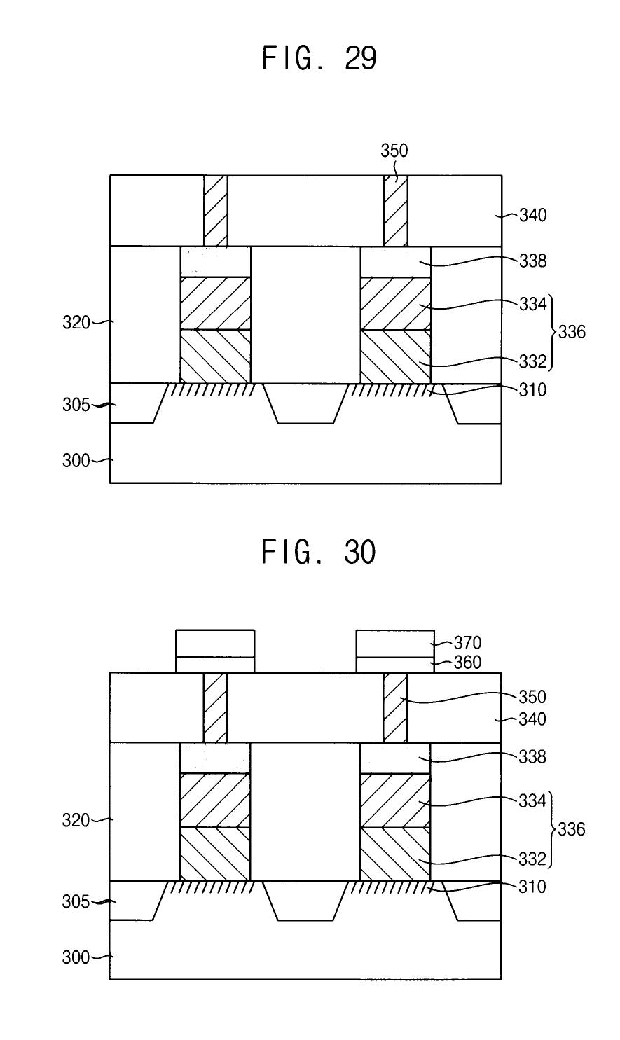

Referring to FIG. 29, a lower electrode 350 filling the second contact hole 345 may be formed on the silicide pattern 338. The lower electrode 350 may be in contact with a phase change layer pattern 360 (see FIG. 30) to generate Joule heating. The lower electrode 350 may have a cross-section smaller than the phase change layer pattern 360 so that a heating efficiency may be enhanced. The lower electrode 350 may be formed using a metal nitride or a metal silicon nitride that may have a resistivity larger than that of a metal. For example, the lower electrode 350 may be formed using titanium nitride, titanium silicon nitride, tungsten nitride, tungsten silicon nitride, etc.

Referring to FIG. 30, a phase change layer and an upper electrode layer may be sequentially formed on the second insulating interlayer 340 and the lower electrode 350. The upper electrode layer and the phase change layer may be patterned to form the phase change layer pattern 360 and an upper electrode 370 sequentially stacked on the lower electrode 350.

In example embodiments, the phase change layer may be formed using a chalcogen compound or a chalcogen compound doped with carbon, nitrogen and/or a metal.

The chalcogen compound may include GeSbSe, SbSe, GeSbTe, SbTe, GeSb, AsSbTe, As—Ge—Sb—Te, As—Ge—Se—Te, SnSbTe, SnInSbTe, etc. The phase change layer may be obtained by a PVD process, a sputtering process, etc. The upper electrode layer may be formed using polysilicon, a metal, a metal nitride, or a metal silicide, etc., by, e.g., a CVD process, an ALD process or a sputtering process.

In one example embodiment, a spacer (not illustrated) may be further formed on a sidewall of the second contact hole 345 to reduce a contact area between the phase change layer pattern 360 and the lower electrode 350 so that the heating efficiency may be more enhanced.

FIGS. 31 to 33 are cross-sectional views illustrating a method of manufacturing a semiconductor device in accordance with some example embodiments. Specifically, FIGS. 31 to 33 illustrate a method of manufacturing a phase change memory device in accordance with some example embodiments.

Referring to FIG. 31, processes substantially the same as or similar to those illustrated with reference to FIGS. 23 to 29 may be performed to form a lower electrode 350a electrically connected to the diode 336.

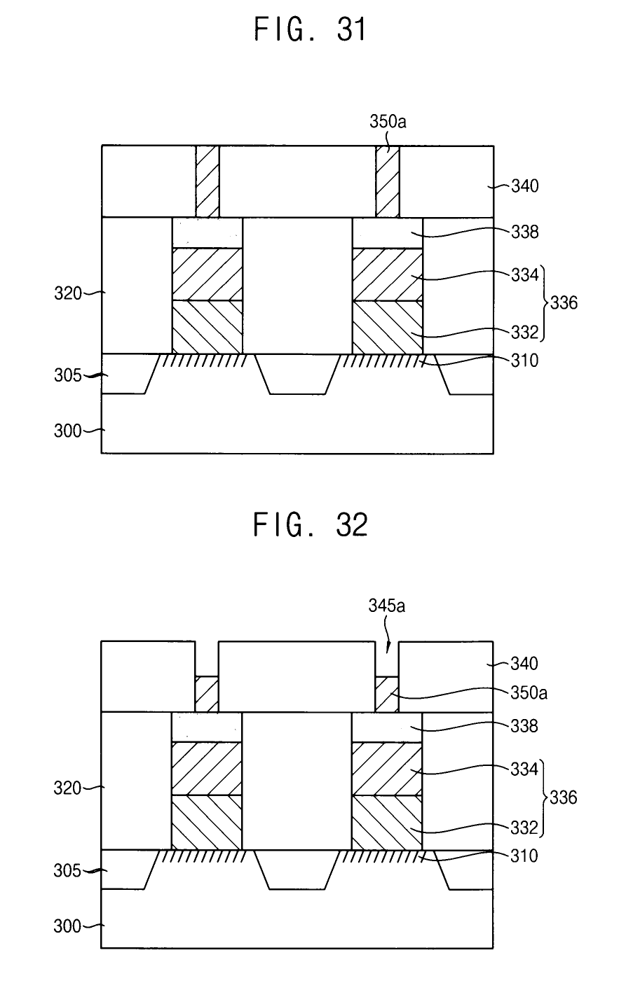

Referring to FIG. 32, an upper portion of the lower electrode 350a may be removed by a dry etching process or a wet etching process to form a third contact hole 345a.

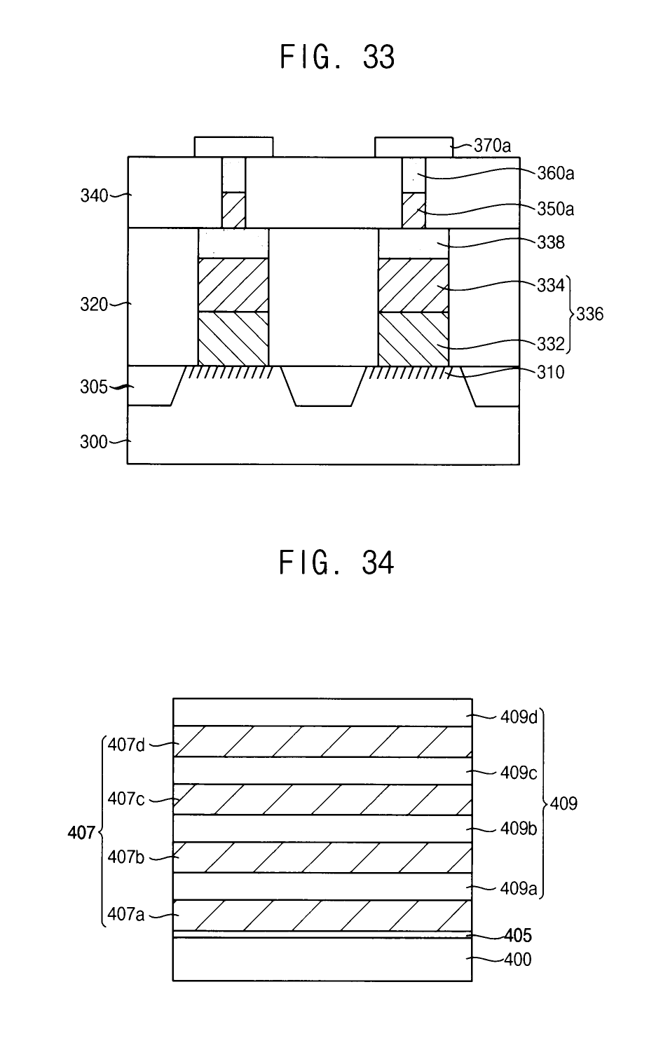

Referring to FIG. 33, a phase change layer pattern 360a filling the third contact hole 345a may be formed to be in contact with the lower electrode 350a. In example embodiments, a phase change layer may be formed on the lower electrode 350a and in the second insulating interlayer 340 to sufficiently fill the third contact hole 345a. The phase change layer may be formed using a chalcogen compound such as GeSbSe, SbSe, GeSbTe, SbTe, GeSb, AsSbTe, SnSbTe, SnInSbTe, etc., by, e.g., a PVD process or a sputtering process. An upper portion of the phase change layer may be planarized until a top surface of the second insulating interlayer 340 is exposed to form the phase change layer pattern 360a.

An upper electrode layer may be formed on the second insulating interlayer 340 and the phase change layer pattern 360a, and then the upper electrode layer may be patterned to form an upper electrode 370a in contact with the phase change layer pattern 360a. The upper electrode layer may be formed using polysilicon, a metal, a metal nitride or a metal silicide, etc., by, e.g., a CVD process, an ALD process or a sputtering process.

As illustrated in FIG. 33, both the lower electrode 350a and the phase change layer pattern 360a may be embedded in one contact hole so that the Joule heating may be transferred uniformly from the lower electrode 350a to the phase change layer pattern 360a.

FIGS. 34 to 42 are cross-sectional views illustrating a method of manufacturing a semiconductor device in accordance with some example embodiments. Specifically, FIGS. 34 to 42 illustrate a method of manufacturing a vertical memory device.

Referring to FIG. 34, a pad insulation layer 405 may be formed on a substrate 400. Sacrificial layers 407 and insulating interlayers 409 may be repeatedly and alternately formed on the pad insulation layer 405 in a direction vertical to a top surface of the substrate 400. As illustrated in FIG. 34, a first sacrificial layer 407a may be formed on the pad insulation layer 405, and a first insulating interlayer 409a may be formed on the first sacrificial layer 407a. Likewise, other sacrificial layers 407b, 407c and 407d and insulating interlayers 409b, 409c and 409d may be sequentially and alternately formed on each other.

The pad insulation layer 405 may reduce stress generated when the first sacrificial layer 407a is formed directly on the substrate 400. The pad insulation layer 405 may be formed by performing a thermal oxidation process on the substrate 400.

The sacrificial layers 407 may be removed by a subsequent process to define regions in which gate structures are formed according to levels of the vertical memory device. The sacrificial layers 407 may be formed using a material that may have an etching selectivity relative to the insulating interlayers 409. In example embodiments, the sacrificial layers 407 and the insulating interlayers 409 may be formed using silicon nitride and silicon oxide, respectively. The sacrificial layers 407 and the insulating interlayers 409 may be formed by a CVD process, a PECVD process, a spin coating process, an HDP-CVD process, etc.

A transistor at each level may be formed in a space generated when the sacrificial layer 407 is removed, and thus the number of the sacrificial layers 407 may be greater than or equal to the number of the transistors in a string, which may include cell transistors and selection transistors.

In example embodiments, the string may include 2 cell transistors and 2 selection transistors. However, the number of the cell transistors and the selection transistors may not be limited thereto and may be properly adjusted as needed.

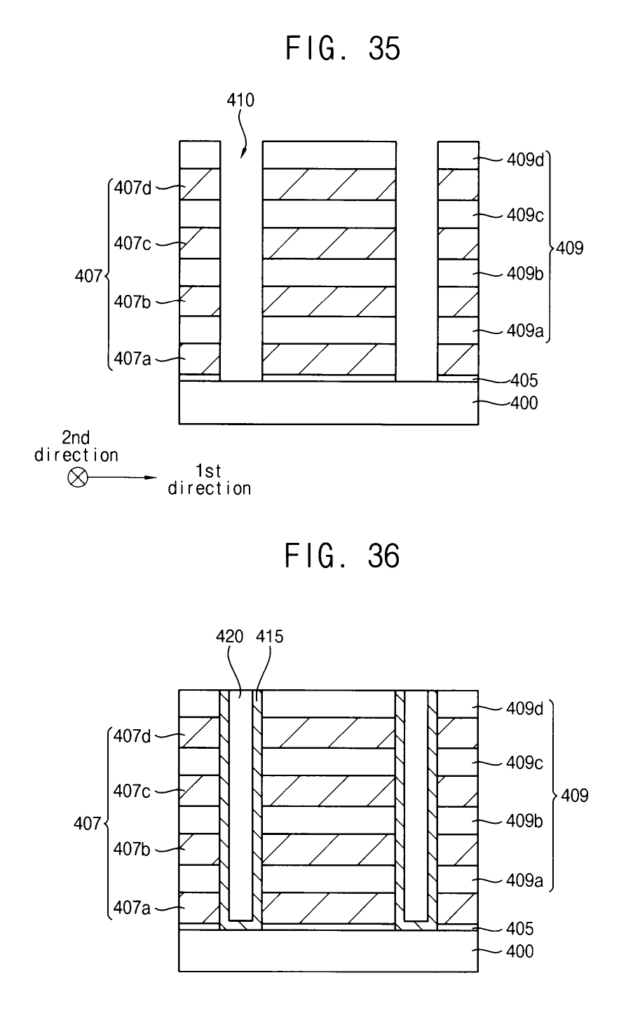

Referring to FIG. 35, a mask pattern (not illustrated) may be formed on the uppermost insulating interlayer 409d and the insulating interlayers 409, the sacrificial layers 407 and the pad insulation layer 405 may be sequentially etched using the mask pattern as an etching mask to form a first hole 410. The top surface of the substrate 400 may be exposed by a bottom of the first hole 410. In example embodiments, a plurality of the first holes 410 may be formed at regular intervals in a first direction and a second direction substantially perpendicular to the first direction.

In example embodiments, the first hole 410 may be formed using the insulating interlayers 409, the sacrificial layers 407 and the pad insulation layer 405 as an object layer by processes substantially the same as or similar to those illustrated with reference to FIGS. 1 to 13 or FIGS. 14 to 22.

Referring to FIG. 36, a semiconductor pattern 415 may be formed on an inner wall of the first hole 410 and on a top surface of the substrate 400. The semiconductor pattern 415 may serve as a channel or an active region of a cell string formed vertically relative to the top surface of the substrate 400. In example embodiments, the semiconductor pattern 415 may have a hollow cylindrical shape or a cup shape. The semiconductor pattern 415 may be formed using polysilicon or amorphous silicon.

An insulation layer sufficiently filling the first hole 410 may be formed on the semiconductor pattern 415 and the uppermost insulating interlayer 409d. An upper portion of the insulation layer may be planarized to form a first insulation layer pattern 420.

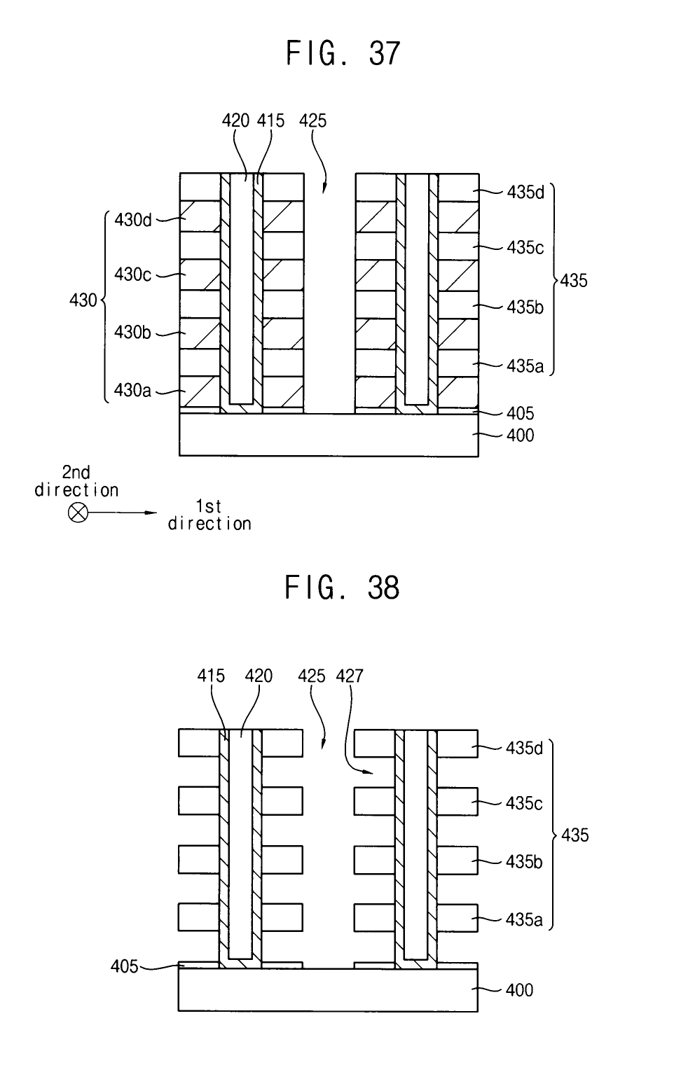

Referring to FIG. 37, the sacrificial layers 407 and the insulating interlayers 409 between the semiconductor patterns 415 may be partially etched to form an opening 425. The opening 425 may extend in the second direction. Sacrificial layer patterns 430 and insulating interlayer patterns 435 extending in the second direction may be formed by forming the opening 425. The sacrificial layer patterns 430 and the insulating interlayer patterns 435 may surround an outer sidewall of the semiconductor patterns 415.

Referring to FIG. 38, the sacrificial layer patterns 430 exposed by a sidewall of the opening 425 may be removed by, e.g., a wet etching process. If the sacrificial layer patterns 430 include silicon nitride, then the sacrificial layer patterns 430 may be removed using an etching solution that includes, for example, sulfuric acid or phosphoric acid.

The insulating interlayer patterns 435 may remain on the outer sidewall of the semiconductor pattern 515 to be spaced apart from one another in the vertical direction relative to the top surface of the substrate 400. A plurality of grooves 427 may be defined by spaces generated when the sacrificial layer patterns 430 are removed to partially expose the outer sidewall of the semiconductor pattern 415.

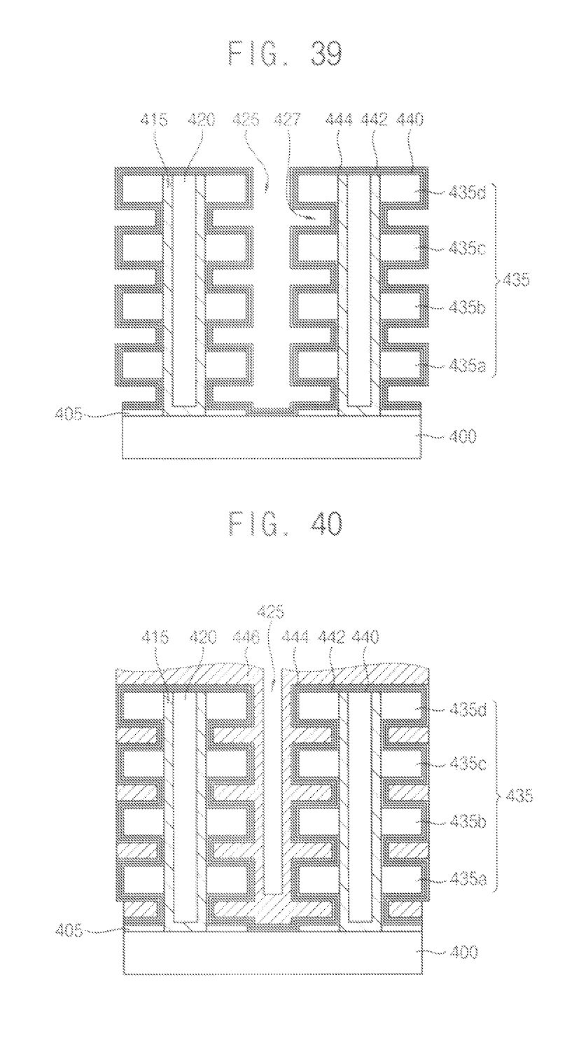

Referring to FIG. 39, a tunnel insulation layer 440, a charge trapping layer 442 and a blocking layer 444 may be formed sequentially along the exposed outer sidewall of the semiconductor pattern 515 and surfaces of the insulating interlayer patterns 435.

The tunnel insulation layer 440 may be formed using silicon oxide by, e.g., a CVD process. Alternatively, the tunnel insulation layer 440 may be formed only on the exposed outer sidewall of the semiconductor pattern 415 by performing a thermal oxidation process thereon.

The charge trapping layer 442 may be formed using silicon nitride or a metal oxide by a CVD process, etc.

The blocking layer 444 may be formed on the charge trapping layer 442. The blocking layer 444 may be formed using silicon oxide or a metal oxide such as aluminum oxide, lanthanum oxide, lanthanum aluminum oxide, lanthanum hafnium oxide, hafnium aluminum oxide, titanium oxide, tantalum oxide, zirconium oxide, etc. These materials may be used alone or in a mixture thereof to form the blocking layer 444.

In example embodiments, the charge trapping layer 442 and the blocking layer 444 may be continuously formed throughout all levels.

Referring to FIG. 40, a conductive layer 446 may be formed on the blocking layer 444 to sufficiently fill the grooves 427. The opening 425 may be partially filled with the conductive layer 446. The conductive layer 446 may be formed using a metal or a metal nitride having a low resistance, for example, tungsten, tungsten nitride, titanium, titanium nitride, tantalum, tantalum nitride or platinum. The conductive layer 446 may be formed by a CVD process, an ALD process, a PVD process, etc.

Referring to FIG. 41, the conductive layer 446 may be partially removed to form gate electrodes 450a, 450b, 450c and 450d in the grooves 427.

For example, an upper portion of the conductive layer 446 may be planarized until an uppermost insulating interlayer pattern 435d is exposed. Portions of the tunnel insulation layer 440, the charge trapping layer 442 and the blocking layer 444 formed on a top surface of the uppermost insulating interlayer pattern 435d may be also removed. A portion of the conductive layer 446 in the opening 425 may be removed by, e.g., a dry etching process to form the gate electrodes 450a, 450b, 450c and 450d. Portions of the tunnel insulation layer 440, the charge trapping layer 442 and the blocking layer 444 formed on the bottom of the opening 425 may be also removed to expose the top surface of the substrate 400.

In some example embodiments, portions of the tunnel insulation layer 440, the charge trapping layer 442 and the blocking layer 444 formed on sidewalls of the insulating interlayer patterns 435 may be also removed together with the portion of the conductive layer 446 in the opening 425. In this case, the tunnel insulation layer 440, the charge trapping layer 442 and the blocking layer 444 at different levels may be separated from each other.

By performing the above processes, a gate structure including the tunnel insulation layer 440, the charge trapping layer 442, the blocking layer 444 and the gate electrode 450 may be formed in each grove 427. In example embodiments, the lowermost gate electrode 450a may serve as a ground selection line (GSL) and the uppermost gate electrode 450d may serve as a string selection line (SSL). The gate electrodes 450b and 450c between the GSL and the SSL may serve as word lines.

Referring now to FIG. 41, an upper portion of the substrate 400 exposed by the opening 425 may be doped with impurities, e.g., n-type impurities to form an impurity region 460. The impurity region 460 may serve as a common source line (CSL). In some example embodiments, a metal silicide pattern 465 may be further formed on the impurity region 460 to reduce resistance of the CSL.

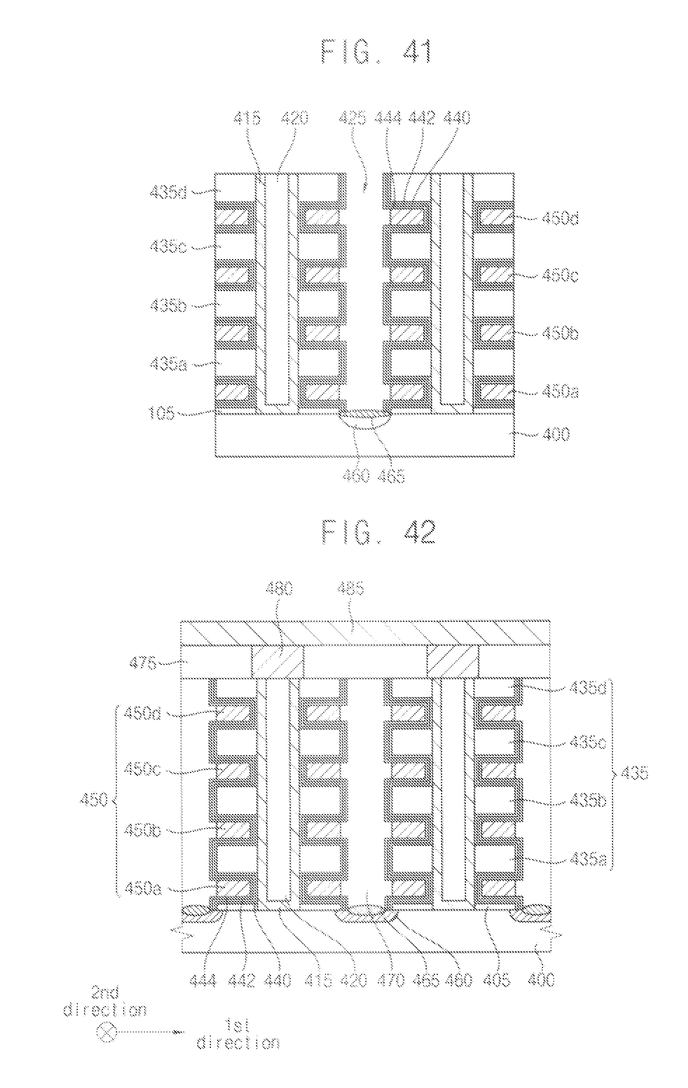

Referring to FIG. 42, an insulation layer may be formed to sufficiently fill the opening 425, and an upper portion of the insulation layer may be planarized to form a second insulation layer pattern 470 in the opening 425. An upper insulating interlayer 475 may be formed on the semiconductor pattern 415, the first insulation layer pattern 420, the second insulation layer pattern 470 and the uppermost insulating interlayer pattern 435d. A bit line contact 480 may be formed through the upper insulating interlayer 475 to contact the semiconductor pattern 415. A bit line 485 electrically connected to the bit line contact 480 may be formed on the upper insulating interlayer 475. The bit line 485 may have a linear shape extending in the first direction and a plurality of the bit lines 485 may be formed along the second direction. The bit line contact 480 and the bit line 485 may be formed using a metal, a metal nitride, doped polysilicon, etc.

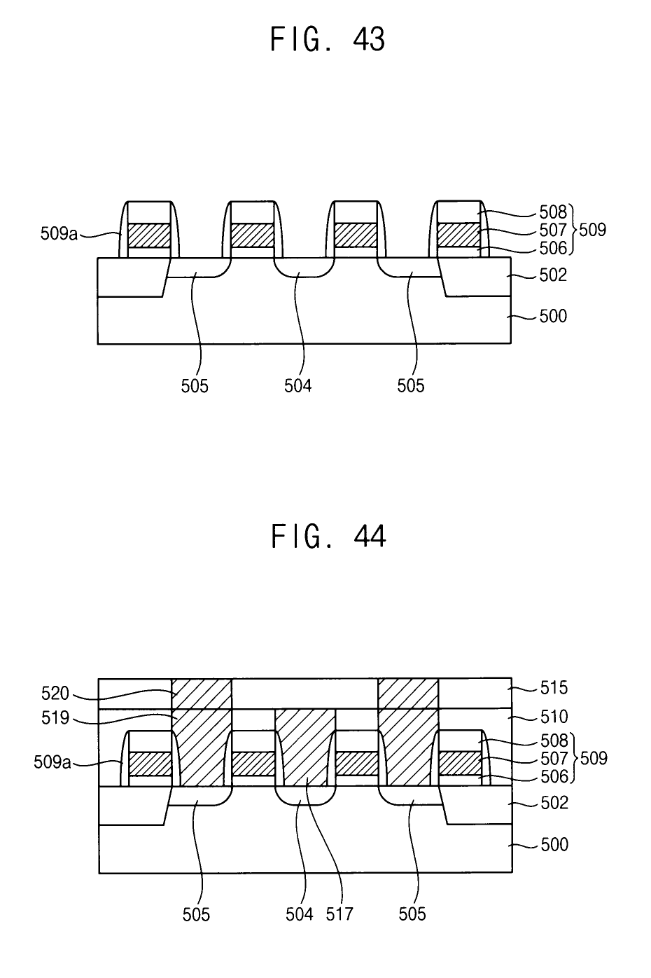

FIGS. 43 to 46 are cross-sectional views illustrating a method of manufacturing a semiconductor device in accordance with some example embodiments. Specifically, FIGS. 43 to 46 illustrate a method of manufacturing a dynamic random access memory (DRAM) device in accordance with some example embodiments.

Referring to FIG. 43, an isolation layer 502 may be formed on a substrate 500. The isolation layer may be formed by a STI process.

A gate insulation layer, a gate electrode layer and a gate mask layer may be sequentially formed on the substrate 500. The gate insulation layer, the gate electrode layer and the gate mask layer may be patterned by, e.g., a photolithography process to form a plurality of gate structures 509 on the substrate 500. Each gate structure 509 may include a gate insulation layer pattern 506, a gate electrode 507 and a gate mask 508 sequentially stacked on the substrate 500. The gate insulation layer may be formed using silicon oxide or a metal oxide. The gate electrode layer may be formed using doped polysilicon or a metal. The gate mask layer may be formed using silicon nitride.

Impurities may be implanted onto the substrate 500 using the gate structure 509 as an ion-implantation mask to form first and second impurity regions 504 and 505 at upper portions of the substrate 500 adjacent to the gate structures 509. Transistors may be defined by the gate structures 509 and the impurity regions 504 and 505. The first and second impurity regions 504 and 505 may serve as source/drain regions of the transistor.

A spacer 509a may be further formed on a sidewall of the gate structure 509. The spacer 509a may include silicon nitride.

Referring to FIG. 44, a first insulating interlayer 510 covering the gate structures 509 and the spacers 509a may be formed on the substrate 500. The first insulating interlayer 510 may be partially removed to form first holes (not illustrated) exposing the impurity regions 504 and 505. In example embodiments, the first holes may be self-aligned with the gate structures 509 and the spacers 509a.

In example embodiments, the first holes may be formed by processes substantially the same as or similar to those illustrated with reference to FIGS. 1 to 13 or FIGS. 14 to 22 using the first insulating interlayer 510 as an object layer.

A first conductive layer filling the first holes may be formed on the substrate 500 and the first insulating interlayer 510. An upper portion of the first conductive layer may be planarized by a CMP process and/or an etch-back process until a top surface of the first insulating interlayer 510 is exposed to form first and second plugs 517 and 519 in the first holes. The first and second plugs 517 and 519 may make contact with the first and second impurity regions 504 and 505, respectively. The first conductive layer may be formed using doped polysilicon, a metal, etc. The first plug 517 may serve as a bit line contact.

A second conductive layer (not illustrated) contacting the first plug 517 may be formed on the first insulating interlayer 510 and the second conductive layer may be patterned to form a bit line (not illustrated). The second conductive layer may be formed using doped polysilicon, a metal, etc.

A second insulating interlayer 515 may be formed on the first insulating interlayer 510 and the first and second plugs 517 and 519. The second insulating interlayer 515 may be partially removed to form second holes (not illustrated) exposing top surfaces of the second plugs 519. The second holes may be formed by processes substantially the same as or similar to those illustrated with reference to FIGS. 1 to 13 or FIGS. 14 to 22 using the second insulating interlayer 515 as an object layer.

A third conductive layer filling the second holes may be formed on the second plugs 519 and the second insulating interlayer 515. An upper portion of the third conductive layer may be planarized by a CMP process and/or an etch-back process until a top surface of the second insulating interlayer 515 is exposed to form third plugs 520 in the second holes. The third conductive layer may be formed using doped polysilicon, a metal, etc. The second and third plugs 519 and 520 may serve as capacitor contacts. Alternatively, the third plug 520 may be formed to make direct contact with the second impurity region 505 through the first and second insulating interlayers 510 and 515 without forming the second plug 519.

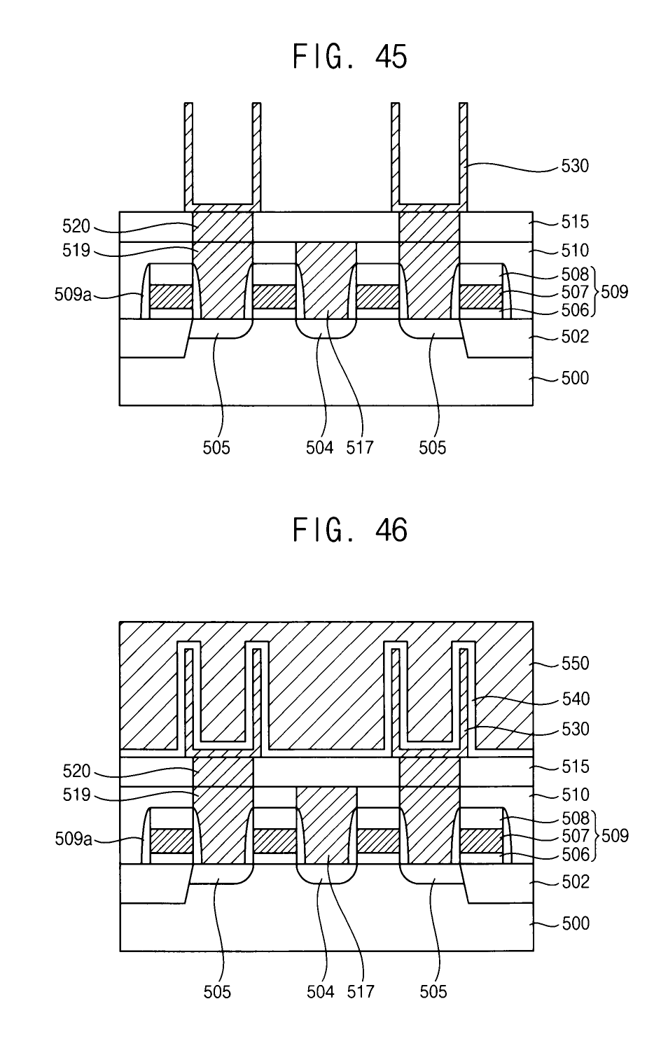

Referring to FIG. 45, an etch-stop layer (not illustrated) and a mold layer (not illustrated) may be formed on the second insulating interlayer 515. The mold layer and the etch-stop layer may be partially removed to form an opening (not illustrated) exposing a top surface of the third plug 520.

A lower electrode layer may be formed on a sidewall and a bottom of the opening and on a top surface of the mold layer. The lower electrode layer may be formed using a metal or a metal nitride, e.g., titanium, titanium nitride, tantalum, tantalum nitride, tungsten nitride, ruthenium, etc., or doped polysilicon. A sacrificial layer may be formed on the lower electrode layer, and then the sacrificial layer and the lower electrode layer may be partially removed to expose the top surface of the mold layer. The sacrificial layer and the mold layer may be removed to form a lower electrode 530 electrically connected to the third plug 520.

Referring to FIG. 46, a dielectric layer 540 covering the lower electrode 530 may be formed on the etch-stop layer and the second insulating interlayer 515. The dielectric layer 540 may be formed using a material that may have a dielectric constant greater than those of silicon oxide or silicon nitride.

The upper electrode 550 may be formed on the dielectric layer 540. The upper electrode 550 may be formed using a metal and/or a metal nitride such as titanium, titanium nitride, tantalum, tantalum nitride, tungsten nitride, ruthenium, etc.

Accordingly, a capacitor including the lower electrode 530, the dielectric layer 540 and the upper electrode 550 may be formed.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of present inventive concepts. Accordingly, all such modifications are intended to be included within the scope of present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming a pattern, comprising:
sequentially forming a first mask layer and a first sacrificial layer on an object layer;
partially etching the first sacrificial layer to form a first sacrificial layer pattern;
forming a second sacrificial layer pattern on the first mask layer, the second sacrificial layer pattern enclosing a sidewall of the first sacrificial layer pattern;
removing the first sacrificial layer pattern;
partially etching the first mask layer using the second sacrificial layer pattern as an etching mask to form a first mask layer pattern; and
partially etching the object layer using the first mask layer pattern as an etching mask.

2. The method of claim 1, wherein the first sacrificial layer includes silicon oxide and the second sacrificial layer pattern includes silicon nitride or silicon oxynitride.

3. The method of claim 2, wherein removing the first sacrificial layer pattern is performed using a hydrofluoric acid (HF) solution or a buffer oxide etchant (BOE) solution.

4. The method of claim 1, wherein the first sacrificial layer pattern includes a plurality of pillars.

5. The method of claim 1, wherein partially etching the first sacrificial layer to form the first sacrificial layer pattern includes:
forming a second mask layer on the first sacrificial layer;
partially etching the second mask layer to form a line pattern extending in a first direction;
partially etching the line pattern to form a second mask layer pattern; and
partially etching the first sacrificial layer using the second mask layer pattern as an etching mask.

6. The method of claim 5, wherein the first mask layer and the second mask layer include polysilicon, and the second mask layer pattern includes a plurality of pillars.

7. The method of claim 5, wherein forming the line pattern includes:
forming a first hard mask pattern extending in the first direction on the second mask layer;
forming first spacers on sidewalls of the first hard mask pattern;
removing the first hard mask pattern; and
partially etching the second mask layer using the first spacer as an etching mask.

8. The method of claim 7, wherein the first hard mask pattern is a silicon based spin-on hard mask (Si—SOH), and the first spacer includes at least one silicon oxide selected from middle temperature oxide (MTO), high temperature oxide (HTO) and atomic layer deposition (ALD) oxide.

9. The method of claim 5, wherein partially etching the line pattern to form the second mask layer pattern includes:
forming a second hard mask pattern on the first sacrificial layer and the line pattern, the second hard mask pattern extending in a second direction perpendicular to the first direction;
forming second spacers on sidewalls of the second hard mask pattern and on the line pattern;
removing the second hard mask pattern; and
partially etching the line pattern using the second spacer as an etching mask.

10. The method of claim 9, wherein the second hard mask pattern is a silicon based spin-on hard mask (Si—SOH), and the second spacer includes at least one silicon oxide selected from middle temperature oxide (MTO), high temperature oxide (HTO) and atomic layer deposition (ALD) oxide.

11. A method of manufacturing a semiconductor device, comprising:
forming a first insulating interlayer on a substrate, the substrate including an impurity region;
forming a first contact hole through the first insulating interlayer to expose the impurity region, the contact hole being formed according to the method of claim 1, wherein the first insulating interlayer is the object layer; and
forming a diode in the first contact hole on the substrate.

12. The method of claim 11, wherein the first sacrificial layer includes silicon oxide, the second sacrificial layer pattern includes silicon nitride or silicon oxynitride, and the first mask layer includes polysilicon.

13. The method of claim 11, wherein forming the diode includes:
forming a conductive pattern in the first contact hole, the conductive layer being in contact with the impurity region; and
implanting impurities into the conductive pattern.

14. The method of claim 11, further comprising:
forming a second insulating interlayer on the first insulating interlayer and the diode;
forming a second contact hole through the second insulating interlayer to expose the diode;
forming a lower electrode in the second contact hole;
forming a phase change layer pattern in contact with the lower electrode; and
forming an upper electrode on the phase change layer pattern.

15. The method of claim 14, wherein forming the second contact hole includes:
sequentially forming a second mask layer and a third sacrificial layer on the second insulating interlayer;
partially etching the third sacrificial layer to form a third sacrificial layer pattern, the third sacrificial layer pattern including a plurality of pillars;
forming a fourth sacrificial layer pattern on the second mask layer, the fourth sacrificial layer pattern enclosing a sidewall of the third sacrificial layer pattern;
removing the third sacrificial layer pattern;
partially etching the second mask layer using the fourth sacrificial layer pattern as an etching mask to form a second mask layer pattern; and
partially etching the second insulating interlayer using the second mask layer pattern as an etching mask.

16. A method of forming a pattern, comprising:
sequentially forming an etch stop layer, a first sacrificial layer, and a first mask layer on an object layer;
etching the first mask layer to form a first mask layer pattern;
etching the first sacrificial layer using the first mask layer pattern as an etching mask to form a first sacrificial layer pattern;
forming a second mask layer on the first sacrificial layer pattern and the etch stop layer;
etching the second mask layer to form a second mask layer pattern and to expose the etch stop layer and the first sacrificial layer pattern;
etching the first sacrificial layer pattern using the second mask layer pattern as an etching mask to form first sacrificial layer pillars and an opening;
forming a third mask layer in the opening;
planarizing the third mask layer to expose the first sacrificial layer pillars;
etching the first sacrificial layer pillars to form holes in the third mask layer; and
etching the etch stop layer and the object layer using the third mask layer as an etching mask.

17. A method of forming a semiconductor device, comprising:
forming a first insulating interlayer on a substrate, the substrate including an impurity region;
forming a contact hole through the first insulating interlayer to expose the impurity region, the contact hole being formed by the method of claim 16, wherein the first insulating interlayer is the object layer; and
forming a diode in the first contact hole on the substrate.

18. A method of forming a pattern, comprising:
sequentially forming a first layer and a second layer on a substrate;
etching the second layer to form a first pattern layer;
forming a second pattern layer on the first pattern layer;
etching the first pattern layer using the second pattern layer as an etching mask to form pillars;
forming a third layer on the first layer, the third layer enclosing the pillars;
etching the pillars; and
etching the first layer and the substrate using the third layer as an etching mask.

19. A method of forming a semiconductor device, the method comprising:
forming a first insulating interlayer on a substrate, the substrate including an impurity region;
forming a first contact hole through the first insulating interlayer to expose the impurity region; and
forming a diode in the first contact hole on the substrate, wherein forming the first contact hole includes,
sequentially forming a first layer and a second layer on the first insulating interlayer;
etching the second layer to form a first pattern layer;
forming a second pattern layer on the first pattern layer;
etching the first pattern layer using the second pattern layer a an etching mask to form pillars;
forming a third layer on the first layer, the third layer enclosing the pillars;
etching the pillars; and
etching the first layer and the first insulating interlayer using the third layer as an etching mask.
